(19) United States
(12) Patent Application Publication
(10) Pub. No.: US 2016/0155868 A1
(43) Pub. Date: Jun. 2, 2016

(54) CRYSTALLINE SILICON SOLAR CELL AND METHOD FOR PRODUCING SAME

(71) Applicant: NAMICS CORPORATION, Niigata (JP)

(72) Inventors: Tetsu TAKAHASHI, Niigata-shi, Niigata (JP); Genki SAITO, Niigata-shi, Niigata (JP)

(73) Assignee: NAMICS CORPORATION, Niigata-shi, Niigata (JP)

(21) Appl. No.: 14/906,438

(22) PCT Filed: Jul. 24, 2014
(86) PCT No.: PCT/JP2014/069566

§ 371 Date: Jan. 20, 2016

(30) Foreign Application Priority Data
Jul. 25, 2013 (JP) 2013-154582

(51) Int. Cl. H01L 31/0368; H01L 31/18; H01L 31/0216

(52) U.S. Cl. CPC H01L 31/03682; H01L 31/02168; H01L 31/182

(57) ABSTRACT

The present invention aims to provide a high performance crystalline silicon solar cell. The present invention is a crystalline silicon solar cell including a first conductivity-type crystalline silicon substrate; an impurity diffusion layer formed on at least a portion of at least one surface of the crystalline silicon substrate; a buffer layer formed on at least a portion of a surface of the impurity diffusion layer; and an electrode formed on a surface of the buffer layer, wherein the electrode includes a conductive metal and a complex oxide, and the buffer layer is a layer comprising silicon, oxygen, and nitrogen.

### TECHNICAL FIELD

The present invention relates to a crystalline silicon solar cell including a substrate made of single-crystalline silicon, multi-crystalline silicon or the like (crystalline silicon substrate). The present invention also relates to a method for producing the crystalline silicon solar cell.

### BACKGROUND ART

In recent years, the amount of production of crystalline silicon solar cells comprising a crystalline silicon substrate, which is formed by processing single-crystalline silicon or multi-crystalline silicon into a plate-like form, has substantially increased. Such solar cells have electrodes for taking out generated power. Conventionally, conductive pastes containing an electrically conductive powder, a glass frit, an organic binder, a solvent, and other additives have been used to form electrodes for crystalline silicon solar cells. As a glass flit to be contained in such a conductive paste, for example, a lead borosilicate-based glass fit, which contains lead oxide, is used.

As a method for producing a solar cell, for example, Patent Document 1 describes a method for producing a semiconductor device (solar cell device). Specifically, Patent Document 1 describes a method of manufacturing a solar cell device, comprising the steps of:

(a) providing one or more semiconductor substrates, one or more insulating films, and a thick film composition, wherein the thick film composition comprises: a) an electrically conductive silver, b) one or more glass fits, c) an Mg-containing additive, dispersed in d) an organic medium,

(b) applying the insulating film on the semiconductor substrate,

(c) applying the thick film composition on the insulating film on the semiconductor substrate, and

(d) firing the semiconductor, insulating film and thick film composition, wherein, upon firing, the organic vehicle is removed, and the silver and glass frits are sintered.

Patent Document 1 further states that the front electrode silver paste of Patent Document 1 is capable of reacting and penetrating through the silicon nitride film (anti-reflection film) during firing to achieve electrical contact with the n-type layer (fire through).

Meanwhile, Non-Patent Document 1 describes the results of a study on glasses in the ternary system, molybdenum oxide, boron oxide, and bismuth oxide, regarding the vitrifiable range of the compositions and the amorphous network of oxides contained in the compositions.

### PRIOR ART DOCUMENTS

### Patent Document

Patent Document 1: JP 2011-503772 A

### Non-Patent Document

Non-Patent Document 1: R. Iordanova, et al., Journal of Non-Crystalline Solids, 357 (2011) pp. 2663-2668

### SUMMARY OF THE INVENTION

### Means for Solving the Problem

In order to obtain a crystalline silicon solar cell with high conversion efficiency, it is an important problem to reduce the electrical resistance (contact resistance) between an electrode on the light incident side (also referred to as “surface electrode”) and an impurity diffusion layer (also referred to as “emitter layer”) formed on the surface of a crystalline silicon substrate. In general, to form an electrode on the light incident side (hereinafter “light-incident side electrode”) of a crystalline silicon solar cell, an electrode pattern of a conductive paste containing silver powder is printed on an emitter layer on the surface of a crystalline silicon substrate, followed by firing. To reduce contact resistance between the light-incident side electrode and the emitter layer of the crystalline silicon substrate, it is necessary to select the type and composition of oxides constituting a complex oxide, such as a glass frit. This is because the type of the complex oxide to be added to a conductive paste for forming a light-incident side electrode affects the properties of the resulting solar cell.

When a conductive paste for forming a light-incident side electrode is fired, the conductive paste fires through an anti-reflection film made of, for example, silicon nitride. As a result, the light-incident side electrode comes into contact with an emitter layer formed on the surface of a crystalline silicon substrate. For a conventional conductive paste to fire through an anti-reflection film, the complex oxide needs to etch the anti-reflection film during firing. However, the action of the complex oxide can go beyond the etching of the anti-reflection film and adversely affect the emitter layer formed on the surface of the crystalline silicon substrate. Such an adverse effect may include, for example, dispersion of unexpected impurities contained in the complex oxide on the impurity diffusion layer. This may in turn adversely affect the p-n junction of the solar cell. Such an adverse effect specifically appears as a reduction in open circuit voltage (Voc), which is one of solar cell characteristics. Furthermore, although the emitter layer formed on the surface of the crystalline silicon substrate is passivated by the formation of an anti-light-reflection film, because the anti-reflection film is fired through due to the formation of the light-incident side electrode, that portion is left with many surface defects. This results in loss of photovoltaic power due to recombination of carriers on the surface of the crystalline silicon substrate directly below the light-incident side electrode. These problems also occur in a back surface electrode-type crystalline silicon solar cell, in which both positive and negative electrodes are disposed on the back surface.

Thus, the present invention aims to provide a high performance crystalline silicon solar cell. In particular, the present invention aims to provide a high performance crystalline silicon solar cell with an improved interface between the electrode and the crystalline silicon substrate. Specifically, the present invention aims to provide a crystalline silicon solar cell having an anti-reflection film made of a silicon nitride thin-film or the like on the surface, wherein, upon formation of a light-incident side electrode, the light-incident side electrode does not adversely affect the solar cell characteristics. Furthermore, the present invention aims to provide a crystalline silicon solar cell having back surface electrodes on the crystalline silicon substrate, wherein, upon formation of electrodes on the back surface, the back surface electrodes do not adversely affect the solar cell characteristics.

Moreover, the present invention aims to provide a method for producing a crystalline silicon solar cell capable of producing a high performance crystalline silicon solar cell.

### Means for Solving the Problem

The present inventors have found that an electrode having low contact resistance to an impurity diffusion layer (emitter layer), in which impurities are diffused, can be formed by incorporating a complex oxide, such as a glass frit, of a predetermined composition in a conductive paste for forming an electrode of a crystalline silicon solar cell, and accomplished the present invention. The present inventors have also found that when, for example, an electrode is formed using a conductive paste, for forming an electrode, that contains a complex oxide of a predetermined composition, a buffer layer with a specific structure is formed at least at a portion between the light-incident side electrode and the crystalline silicon substrate and directly below the light-incident side electrode. The inventors have further found that the presence of the buffer layer helps improve the performance of the crystalline silicon solar cell and have accomplished the present invention.

The present invention is based on the above-described findings and has the following structures. The present invention relates to crystalline silicon solar cells of Configurations 1-16 described below and a method for producing the crystalline silicon solar cells of Configurations 17-32 described below.

(Configuration 1)

Configuration 1 of the present invention is a crystalline silicon solar cell comprising a first conductivity-type crystalline silicon substrate; an impurity diffusion layer formed on at least a portion of at least one surface of the crystalline silicon substrate; a buffer layer formed on at least a portion of a surface of the impurity diffusion layer; and an electrode formed on a surface of the buffer layer, wherein the electrode contains a conductive metal and a complex oxide, and the buffer layer is a layer containing silicon, oxygen, and nitrogen. With the crystalline silicon substrate having a predetermined buffer layer, a high performance crystalline silicon solar cell can be obtained.

(Configuration 2)

Configuration 2 of the present invention is the crystalline silicon solar cell of Configuration 1 wherein the buffer layer contains a conductive metallic element, silicon, oxygen, and nitrogen. To achieve a high performance crystalline silicon solar cell, the crystalline silicon substrate preferably has a buffer layer that contains a conductive metallic element in addition to silicon, oxygen, and nitrogen.

(Configuration 3)

Configuration 3 of the present invention is the crystalline silicon solar cell of Configuration 2 wherein the conductive metallic element contained in the buffer layer is silver. Silver can preferably be used as a conductive metallic element to be contained in the buffer layer because silver has low electrical resistivity.

(Configuration 4)

Configuration 4 of the present invention is the crystalline silicon solar cell of any one of Configurations 1-3, including an anti-reflection film made of silicon nitride on at least a portion of the surface of the impurity diffusion layer corresponding to a portion where the electrode is not formed, wherein the impurity diffusion layer is a second conductivity-type impurity diffusion layer formed on the light incident side surface of the first conductivity-type crystalline silicon substrate, and the electrode is a light-incident side electrode formed on the light incident side surface of the crystalline silicon substrate. The formation of a predetermined buffer layer directly below the light-incident side electrode of the crystalline silicon solar cell leads to a higher performance crystalline silicon solar cell. The formation of the light-incident side electrode on the surface where the anti-reflection film of silicon nitride is disposed ensures the formation of a buffer layer containing silicon, oxygen, and nitrogen.

(Configuration 5)

Configuration 5 of the present invention is the crystalline silicon solar cell of Configuration 4 wherein the light-incident side electrode includes a finger electrode section for electrically contacting the impurity diffusion layer, and a bus bar electrode section for electrically contacting the finger electrode section and a conductive ribbon for taking out current to the outside, wherein the buffer layer is formed between the finger electrode section and the crystalline silicon substrate, and at at least a portion directly below the finger electrode section. The finger electrode section plays the role of collecting current from the impurity diffusion layer. Thus, the configuration where the buffer layer is formed directly below the finger electrode section further ensures production of a high performance crystalline silicon solar cell.

(Configuration 6)

Configuration 6 of the present invention is the crystalline silicon solar cell of Configuration 4 or 5 which includes a back surface electrode on a back surface of the crystalline silicon substrate, opposite from the surface on the light incident side. The crystalline silicon solar cell including a back surface electrode can take out current to the outside from the light incident side electrode and the back surface electrode.

(Configuration 7)

Configuration 7 of the present invention is the crystalline silicon solar cell of any one of Configurations 1-3 wherein the impurity diffusion layer consists of a first conductivity-type impurity diffusion layer and a second conductivity-type impurity diffusion layer both formed on the back surface of the first conductivity-type crystalline silicon substrate, opposite from the surface on the light incident side, the first conductivity-type impurity diffusion layer and the second conductivity-type impurity diffusion layer, each formed in the shape of a comb and disposed to interdigitate with each other, the buffer layer consists of a buffer layer formed on at least a portion of a surface of the first conductivity-type impurity diffusion layer and a buffer layer formed on at least a portion of a surface of the second conductivity-type impurity diffusion layer, and the electrode includes a first electrode, which is formed on a surface of the buffer layer formed on the at least a portion of the surface of the first conductivity-type impurity diffusion layer, and a second electrode, which is formed on a surface of the buffer layer formed on the at least a portion of the surface of the second conductivity-type impurity diffusion layer. When a predetermined buffer layer is formed directly below the back surface electrode in a back surface electrode-type crystalline silicon solar cell, which includes both negative and positive electrodes on the back surface, a high performance crystalline silicon solar cell can be obtained.

(Configuration 8)

Configuration 8 of the present invention is the crystalline silicon solar cell of Configuration 7, including a silicon nitride film made of silicon nitride on at least a portion of the back surface of the first conductivity-type crystalline silicon substrate and the impurity diffusion layer corresponding to a portion where the electrodes are not formed. The formation of a back surface electrode on the back surface where the silicon nitride film of silicon nitride is formed ensures the formation of a buffer layer containing silicon, oxygen, and nitrogen between the back surface electrode and the crystalline silicon substrate.

(Configuration 9)

Configuration 9 of the present invention is the crystalline silicon solar cell of any one of Configurations 1-7 wherein at least a portion of the buffer layer includes a silicon oxynitride film and a silicon oxide film, in the recited order, from the crystalline silicon substrate toward the electrodes. The crystalline silicon solar cell having a buffer layer of a predetermined structure ensures high performance.

(Configuration 10)

Configuration 10 of the present invention is the crystalline silicon solar cell of Configuration 9 wherein the buffer layer contains conductive particulates of a conductive metallic element. Because of the conductivity of the conductive particulates, the buffer layer containing the conductive particulates further ensures a higher performance crystalline silicon solar cell.

(Configuration 11)

Configuration 11 of the present invention is the crystalline silicon solar cell of Configuration 10 wherein the conductive particulates have a particle size of 20 nm or less. The conductive particulates having a predetermined particle size can be stably present within the buffer layer.

(Configuration 12)

Configuration 12 of the present invention is the crystalline silicon solar cell of Configuration 10 or 11 wherein the conductive particulates are present only within the silicon oxide film of the buffer layer. It may be inferred that the conductive particulates being present only within the silicon oxide film of the buffer layer results in a higher performance crystalline silicon solar cell.

(Configuration 13)

Configuration 13 of the present invention is the crystalline silicon solar cell of any one of Configurations 10-12 wherein the conductive particulates are silver particulates. Silver powder is highly conductive and has conventionally been used as an electrode in many crystalline silicon solar cells and is highly reliable. When silver powder is used as a conductive powder in producing a crystalline silicon solar cell, silver particulates serve as the conductive particulates within the buffer layer. As a result, a highly reliable, high performance crystalline silicon solar cell can be produced.

(Configuration 14)

Configuration 14 of the present invention is the crystalline silicon solar cell of any one of Configurations 1-13 wherein the buffer layer disposed between the electrode and the impurity diffusion layer has an area not less than 5% of the area directly below the electrode. When the area of the buffer layer directly below the light-incident side electrode accounts for the predetermined percentage or more, a high performance crystalline silicon solar cell can be produced more reliably.

(Configuration 15)

Configuration 15 of the present invention is the crystalline silicon solar cell of any one of Configurations 1-14 wherein the complex oxide contained in the electrode contains molybdenum oxide, boron oxide, and bismuth oxide. With the complex oxide containing the three components (molybdenum oxide, boron oxide, and bismuth oxide), the structure of the high performance crystalline silicon solar cell of the present invention can be achieved more reliably.

(Configuration 16)

Configuration 16 of the present invention is the crystalline silicon solar cell of Configuration 15 wherein, when the total of molybdenum oxide, boron oxide, and bismuth oxide is taken as 100 mol %, the complex oxide contains 25-65 mol % of molybdenum oxide, 5-45 mol % of boron oxide, and 25-35 mol % of bismuth oxide. Containing a complex oxide of a predetermined composition leads to a favorable electrical contact with low contact resistance between the predetermined electrode of the crystalline silicon solar cell and the impurity diffusion layer without adversely affecting the solar cell characteristics.

(Configuration 17)

Configuration 17 of the present invention is a method for producing a crystalline silicon solar cell, comprising the steps of preparing a first conductivity-type crystalline silicon substrate; forming an impurity diffusion layer on at least a portion of at least one surface of the crystalline silicon substrate; forming a silicon nitride film on the surface of the impurity diffusion layer, and printing and firing a conductive paste on a surface of the silicon nitride film, which is formed on the surface of the impurity diffusion layer, to form an electrode and a buffer layer between the electrode and the impurity diffusion layer, wherein the buffer layer is a layer containing silicon, oxygen, and nitrogen. By forming the electrode of the crystalline silicon solar cell by firing the above-described conductive paste of the present invention, a high performance crystalline silicon solar cell having a predetermined buffer layer of the present invention can be produced.

(Configuration 18)

Configuration 18 of the present invention is a method for producing the crystalline silicon solar cell of Configuration 17 wherein the buffer layer is a layer containing a conductive metallic element, silicon, oxygen, and nitrogen. To achieve a high performance crystalline silicon solar cell, the crystalline silicon substrate has a preferable buffer layer that contains a conductive metallic element in addition to silicon, oxygen, and nitrogen.

(Configuration 19)

Configuration 19 of the present invention is the method for producing a crystalline silicon solar cell of Configuration 18 wherein the conductive metallic element contained in the buffer layer is silver. Because of the low electrical resistivity, silver can be favorably used as a conductive metallic element to be contained in the buffer layer.

(Configuration 20)

Configuration 20 of the present invention is the method for producing a crystalline silicon solar cell of any one of Configurations 17-19 wherein the impurity diffusion layer is a second conductivity-type impurity diffusion layer formed on the light incident side surface of the first conductivity-type crystalline silicon substrate, and the electrode is a light-incident side electrode formed on the light incident side surface of the crystalline silicon substrate. The formation of the predetermined buffer layer directly below the light-incident side electrode leads to a higher performance crystalline silicon solar cell. Furthermore, the formation of a light-incident side electrode on the surface where an anti-reflection film made of silicon nitride is formed ensures the formation of a buffer layer containing silicon, oxygen, and nitrogen.

(Configuration 21)

Configuration 21 of the present invention is a method for producing the crystalline silicon solar cell of Configuration 20 wherein the light-incident side electrode includes a finger electrode section for electrically contacting an impurity diffusion layer, and a bus bar electrode section for electrically contacting the finger electrode section and a conductive ribbon for taking out current to the outside, wherein the buffer layer is formed between the finger electrode section and the crystalline silicon substrate, and at at least a portion directly below the finger electrode section. The finger electrode section plays the role of collecting current from the impurity diffusion layer. Thus, forming a buffer layer directly below the finger electrode section further ensures the production of a high performance crystalline silicon solar cell.

(Configuration 22)

Configuration 22 of the present invention is the method for producing a crystalline silicon solar cell of Configuration 20 or 21, further comprising the step of forming a back surface electrode on a back surface of the crystalline silicon substrate, opposite from the surface on the light incident side. Forming a back surface electrode in a crystalline silicon solar cell enables taking out of current to the outside from the light incident side electrode and the back surface electrode.

(Configuration 23)

Configuration 23 of the present invention is the method for producing a crystalline silicon solar cell of any one of Configurations 17-19 wherein the step of forming an impurity diffusion layer includes forming a first conductivity-type impurity diffusion layer and a second conductivity-type impurity diffusion layer on a back surface, which is a surface of the first conductivity-type crystalline silicon substrate, opposite from the surface on the light incident side, wherein the first conductivity-type impurity diffusion layer and the second conductivity-type impurity diffusion layer, each formed in the shape of a comb and disposed to interdigitate with each other, wherein the buffer layer includes a buffer layer formed on at least a portion of a surface of the first conductivity-type impurity diffusion layer and a buffer layer formed on at least a portion of a surface of the second conductivity-type impurity diffusion layer, and the electrode includes a first electrode formed on a surface of the buffer layer disposed on at least a portion of the surface of the first conductivity-type impurity diffusion layer, and a second electrode formed on a surface of the buffer layer disposed on at least a portion of the surface of the second conductivity-type impurity diffusion layer. When a predetermined buffer layer is formed directly below the back surface electrode in a back surface electrode-type crystalline silicon solar cell, which includes both negative and positive electrodes on the back surface, a high performance crystalline silicon solar cell can be obtained.

(Configuration 24)

Configuration 24 of the present invention is the method for producing a crystalline silicon solar cell of Configuration 23, wherein the step of forming a silicon nitride film includes forming a silicon nitride film made of silicon nitride on the back surface of the first conductivity-type crystalline silicon substrate corresponding to a portion where the electrodes are not formed and on at least a portion of the impurity diffusion layer. By forming a back electrode on the back surface where a silicon nitride film made of silicon nitride is disposed, a buffer layer containing silicon, oxygen, and nitrogen between the back surface electrode and the crystalline silicon substrate can be produced more reliably.

(Configuration 25)

Configuration 25 of the present invention is the method for producing a crystalline silicon solar cell of any one of Configurations 17-24, wherein at least a portion of the buffer layer includes a silicon oxynitride film and a silicon oxide film, in the recited order, from the crystalline silicon substrate toward the light-incident side electrode. A high performance crystalline silicon solar cell can be produced more reliably by having a buffer layer with the predetermined structure.

(Configuration 26)

Configuration 26 of the present invention is the method for producing the crystalline silicon solar cell of any one of Configurations 17-25 wherein the step of forming the electrode includes firing a conductive paste at 400-850° C. A high performance crystalline silicon solar cell with a predetermined structure of the present invention can be produced more reliably, by firing a conductive paste within a predetermined temperature range.

(Configuration 27)

Configuration 27 of the present invention is the method for producing the crystalline silicon solar cell of any one of Configurations 17-26 wherein the conductive paste includes an electrically conductive powder, a complex oxide, and an organic vehicle, and the complex oxide contains molybdenum oxide, boron oxide, and bismuth oxide. By forming an electrode using a conductive paste that contains an electrically conductive powder, a complex oxide, and an organic vehicle, wherein the complex oxide contains molybdenum oxide, boron oxide, and bismuth oxide, on the surface of the crystalline silicon substrate, the predetermined buffer layer can be produced more reliably. This in turn enables reducing contact resistance between the predetermined electrode of the crystalline silicon solar cell and the impurity diffusion layer more reliably.

(Configuration 28)

Configuration 28 of the present invention is the method for producing the crystalline silicon solar cell of Configuration 27 wherein, when the total of molybdenum oxide, boron oxide, and bismuth oxide is taken as 100 mol %, the complex oxide contains 25-65 mol % of molybdenum oxide, 5-45 mol % of boron oxide, and 25-35 mol % of bismuth oxide. By setting the complex oxide to be contained in the conductive paste to have a predetermined composition, a solar cell capable of achieving a favorable electrical contact with low contact resistance between the predetermined electrode of the crystalline silicon solar cell and the impurity diffusion layer can be produced more reliably without adversely affecting the solar cell characteristics.

(Configuration 29)

Configuration 29 of the present invention is the method for producing the crystalline silicon solar cell of Configuration 27 wherein, when the total of molybdenum oxide, boron oxide, and bismuth oxide is taken as 100 mol %, the complex oxide contains 15-40 mol % of molybdenum oxide, 25-45 mol % of boron oxide, and 25-60 mol % of bismuth oxide. With a complex oxide of a predetermined composition, a solar cell capable of achieving a favorable electrical contact with low contact resistance between the predetermined electrode of the crystalline silicon solar cell and the impurity diffusion layer can be produced more reliably without adversely affecting the solar cell characteristics.

(Configuration 30)

Configuration 30 of the present invention is the method for producing the crystalline silicon solar cell of any one of Configurations 27-29 wherein the complex oxide contains 90 mol % or more of molybdenum oxide, boron oxide, and bismuth oxide in total relative to 100 mol % of the complex oxide. By containing at least a predetermined percentage of the three components: molybdenum oxide, boron oxide, and bismuth oxide, a solar cell capable of achieving a favorable electrical contact with low contact resistance between the predetermined electrode of the crystalline silicon solar cell and the impurity diffusion layer can be produced more reliably without adversely affecting the solar cell characteristics.

(Configuration 31)

Configuration 31 of the present invention is the method for producing the crystalline silicon solar cell of any one of Configurations 27-30 wherein the complex oxide further contains 0.1-6 mol % of titanium oxide relative to 100 mol % of the complex oxide. With the complex oxide further containing a predetermined percentage of titanium oxide, a more favorable electrical contact can be achieved.

(Configuration 32)

Configuration 32 of the present invention is the method for producing the crystalline silicon solar cell of any one of Configurations 27-31 wherein the complex oxide further contains 0.1-3 mol % of zinc oxide relative to 100 mol % of the complex oxide. With the complex oxide further containing a predetermined percentage of zinc oxide, a more favorable electrical contact can be achieved.

(Configuration 33)

Configuration 33 of the present invention is the method for producing the crystalline silicon solar cell of any one of Configurations 27-32 wherein the conductive paste contains 0.1-10 parts by weight of the complex oxide relative to 100 parts by weight of the electrically conductive powder. By setting the content of the non-conductive complex oxide to a predetermined range relative to the content of the electrically conductive powder, increase in electrical resistance of the electrode to be formed can be suppressed.

(Configuration 34)

Configuration 34 of the present invention is the method for producing the crystalline silicon solar cell of any one of Configurations 27-33 wherein the electrically conductive powder is silver powder. Silver powder is highly conductive and has conventionally been used as an electrode in many crystalline silicon solar cells, and is highly reliable. In the conductive paste of the present invention as well, using silver powder as an electrically conductive powder enables production of a highly reliable, high performance crystalline silicon solar cell.

### Effect of the Invention

According to the present invention, a high performance crystalline silicon solar cell can be obtained. Specifically, according to the present invention, a high performance crystalline silicon solar cell with an improved interface between the electrode and the crystalline silicon substrate can be obtained.

The present invention provides a crystalline silicon solar cell having an anti-reflection film made of a silicon nitride thin-film or the like on a surface, wherein, upon formation of a light-incident side electrode, the light-incident side electrode does not adversely affect the solar cell characteristics. Furthermore, the present invention provides a crystalline silicon solar cell having a back surface electrode on a back surface of a crystalline silicon substrate, wherein, upon formation of the back surface electrode, the back surface electrode does not adversely affect the solar cell characteristics.

Furthermore, the present invention provides a method for producing a crystalline silicon solar cell, capable of producing a high performance crystalline silicon solar cell.

### BRIEF DESCRIPTION OF THE DRAWINGS

FIG. 1 is a schematic cross-sectional view of a crystalline silicon solar cell.

FIG. 2 is an illustrating view based on the ternary composition diagram of a ternary glass containing molybdenum oxide, boron oxide, and bismuth oxide.

FIG. 3 is a scanning electron microscopy (SEM) micrograph of a cross-sectional view around the interface between a single-crystalline silicon substrate and a light-incident side electrode of a crystalline silicon solar cell (a single-crystalline silicon solar cell) according to a conventional art.

FIG. 4 is an SEM micrograph of a cross-sectional view around the interface between a single-crystalline silicon substrate and a light-incident side electrode of a crystalline silicon solar cell (a single-crystalline silicon solar cell) according to the present invention.

FIG. 5 is a transmission electron microscope micrograph (TEM) micrograph of the cross-sectional view of the crystalline silicon solar cell of FIG. 4, wherein the area around the interface between the single-crystalline silicon substrate and the light-incident side electrode is enlarged.

FIG. 6 is a schematic view for explanation of a transmission electron microscope micrograph of FIG. 5.

FIG. 7 is a schematic plan view illustrating a pattern for measuring contact resistance used to measure the contact resistance between an electrode and a crystalline silicon substrate.

FIG. 8 is a graph showing the results of measurements of saturation current densities (J₀₁) of the emitter layers directly below the light-incident side electrodes of the single-crystalline silicon solar cells of Experiment 5.

FIG. 9 is a graph showing the results of measurements of the open circuit voltages (Voc) of the single-crystalline silicon solar cells of Experiment 6.

FIG. 10 is a graph showing the results of measurements of saturation current densities (J₀₁) of the single-crystalline silicon solar cells of Experiment 6.

FIG. 11 is a schematic view of the light-incident side electrode of the single-crystalline silicon solar cell of Experiment 6 wherein the dummy finger electrode section between the connecting finger electrode sections consists of a single dummy electrode.

FIG. 12 is a schematic view of the light-incident side electrode of the single-crystalline silicon solar cell of Experiment 6 wherein the dummy finger electrode section between the connecting finger electrode sections consists of two dummy electrodes.

FIG. 13 is a schematic view of the light-incident side electrode of the single-crystalline silicon solar cell of Experiment 6 wherein the dummy finger electrode section between the connecting finger electrode sections consists of three dummy electrodes.

### MODE FOR CARRYING OUT THE INVENTION

As used herein, “crystalline silicon” encompasses single-crystalline silicon and multi-crystalline silicon. Furthermore, a “crystalline silicon substrate” means a crystalline silicon material molded into a suitable form, e.g., a plate-like form for forming an element, such as an electrical element or an electronic element. Any method of producing crystalline silicon may be employed. For example, for single-crystalline silicon, the Czochralski method may be used, and for multi-crystalline silicon, a casting method may be used. In addition, crystalline silicon produced by other methods, such as multi-crystalline silicon ribbon produced by the ribbon pulling method, as well as multi-crystalline silicon formed on a different substrate, such as glass, may also be used as a crystalline silicon substrate. Furthermore, a “crystalline silicon solar cell” means a solar cell produced by using a crystalline silicon substrate.

The indicators of solar cell characteristics generally used are: conversion efficiency (η), open circuit voltage (Voc), short circuit current (Isc), and fill factor (hereinafter also referred to as “FF”), which are determined by the measurements of current-voltage characteristics under light irradiation. Furthermore, in particular, to evaluate the performance of an electrode, the contact resistance of the electrode, which is the electrical resistance between the electrode and the impurity diffusion layer of crystalline silicon, may be evaluated. An impurity diffusion layer (also referred to as “emitter layer”) is a layer on which p-type or n-type impurities are diffused so that the density of the impurities is higher than that of the impurities in the silicon substrate, which serves as a base. As used herein, “first conductivity-type” means either p-type or n-type conductivity-type, whereas “second conductivity-type” means the conductivity-type different from the type of the “first conductivity-type”. For example, if the “first conductivity-type crystalline silicon substrate” is a p-type crystalline silicon substrate, then the “second conductivity-type impurity diffusion layer” is an n-type impurity diffusion layer (n-type emitter layer).

First, the structure of the crystalline silicon solar cell of the present invention will be explained.

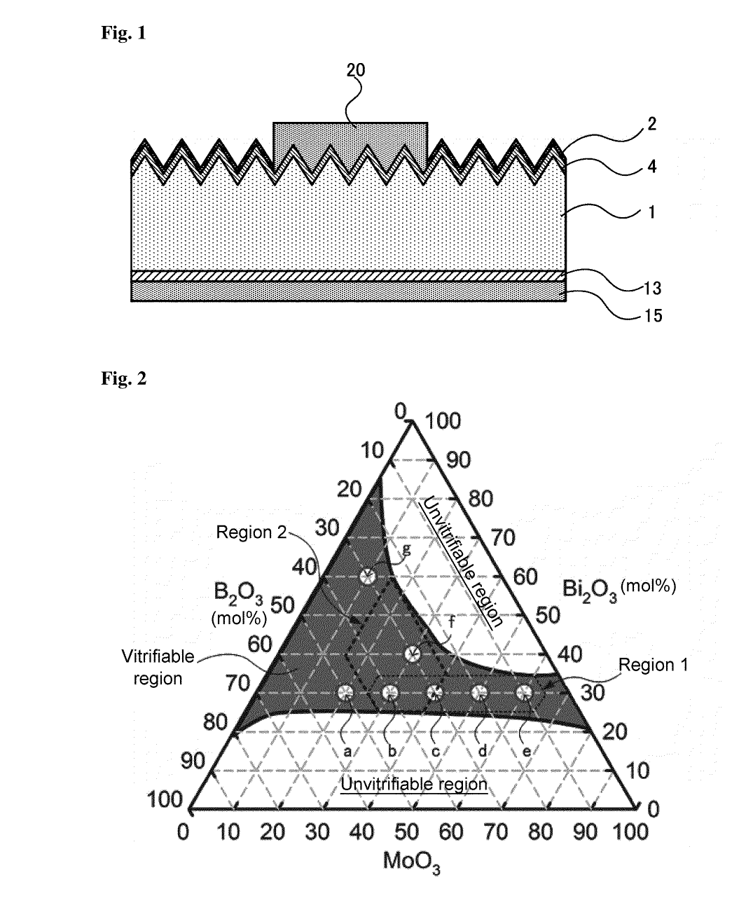

FIG. 1 is a schematic cross-sectional view around a light-incident side electrode of a crystalline silicon solar cell that has electrodes on both light incident side and back surface side (light-incident side electrode 20 and back surface electrode 15). The crystalline silicon solar cell shown in FIG. 1 has a light-incident side electrode 20 formed on the light incident side, an anti-reflection film 2, an impurity diffusion layer 4 (e.g., n-type impurity diffusion layer 4), a crystalline silicon substrate 1 (e.g., p-type crystalline silicon substrate 1), and a back surface electrode 15.

The present inventors have found that when an electrode is formed by using a conductive paste of the present invention that contains a complex oxide 24 of a predetermined composition, a buffer layer 30 of a specific structure is formed between the light-incident side electrode 20 and the crystalline silicon substrate 1 and at at least a portion directly below the light-incident side electrode 20, whereby the performance of a crystalline silicon solar cell is improved.

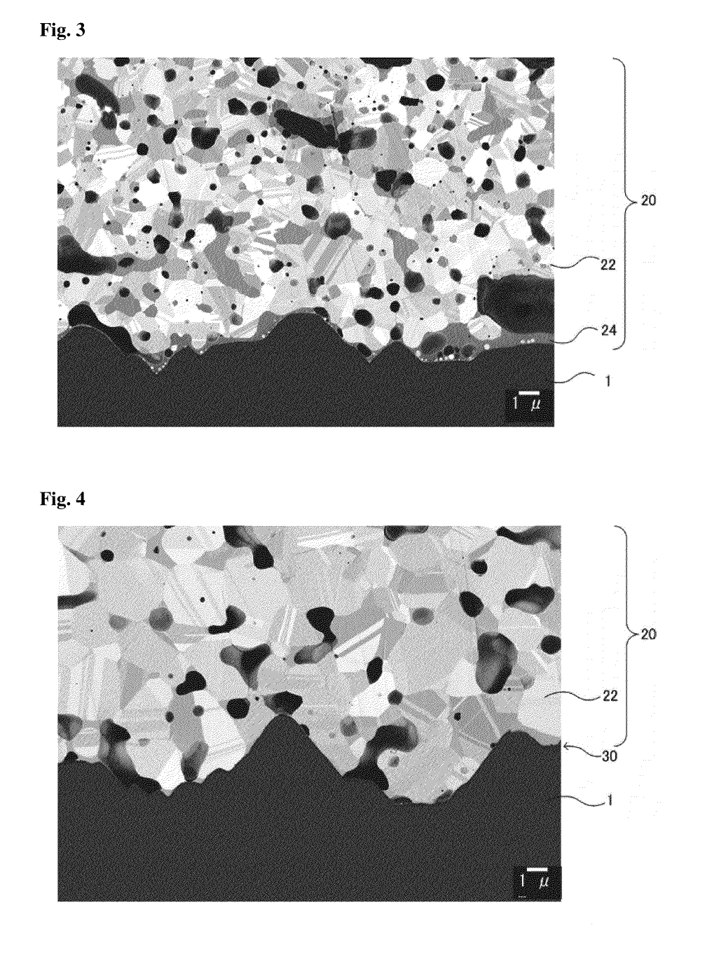

Specifically, the present inventors closely observed a cross section of a test product of a crystalline silicon solar cell according to the present invention using a scanning electron microscopy (SEM). FIG. 4 shows a scanning electron microscopy micrograph of a cross section of a crystalline silicon solar cell of the present invention. For comparison, FIG. 3 shows a scanning electron microscopy micrograph of a cross section of a crystalline silicon solar cell with a conventional structure formed by using a conventional conductive paste for forming an electrode for a solar cell. As shown in FIG. 4, the crystalline silicon solar cell of the present invention obviously has many more portions where silver 22 and the p-type crystalline silicon substrate 1 are in contact with each other in the light-incident side electrode 20 compared to the crystalline silicon solar cell of the comparative example shown in FIG. 3. The structure of the crystalline silicon solar cell according to the present invention can be said to have a different structure from the structure of the conventional crystalline silicon solar cell.

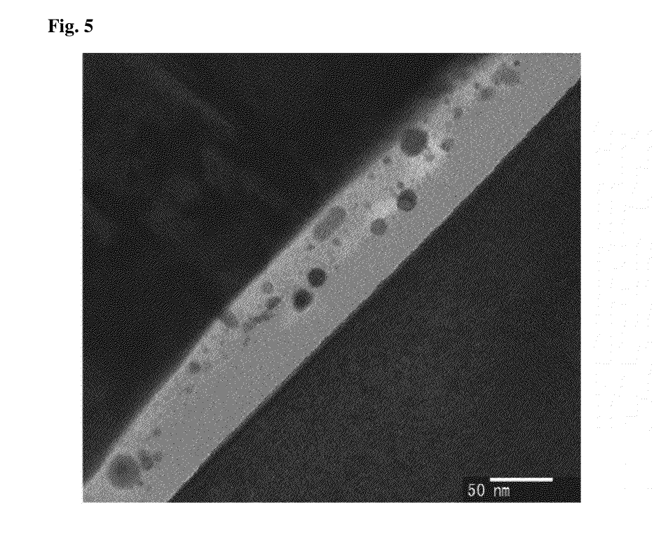

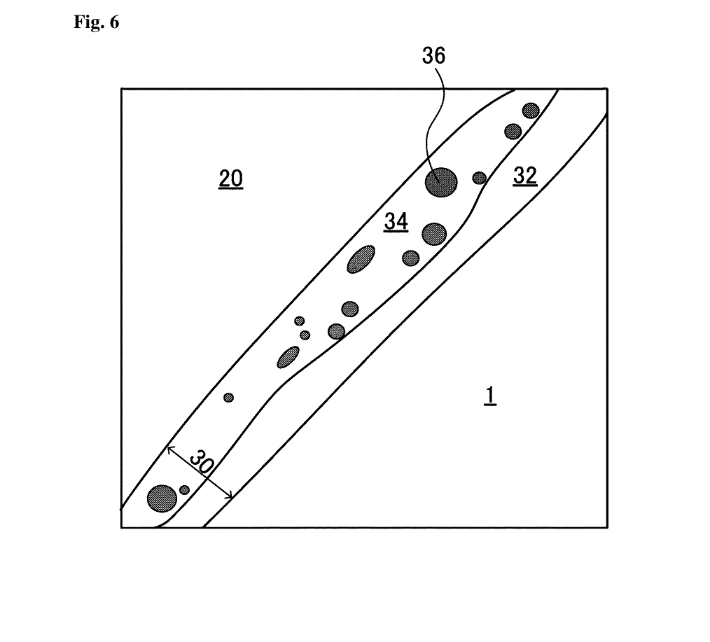

The present inventors further closely observed the structure around the interface between the crystalline silicon substrate 1 and the light-incident side electrode of the crystalline silicon solar cell of the present invention using a transmission electron microscope (TEM). FIG. 5 shows a TEM micrograph of a cross section of a crystalline silicon solar cell according to the present invention. Furthermore, FIG. 6 shows an illustrative view of the TEM micrograph of FIG. 5. Referring to FIGS. 5 and 6, a buffer layer 30 is formed at at least a portion directly below the light-incident side electrode 20 in the crystalline silicon solar cell of the present invention. Hereinbelow, the structure of the crystalline silicon solar cell of the present invention will be specifically described.

Next, the crystalline silicon solar cell of the present invention will be described.

The crystalline silicon solar cell of the present invention has a first conductivity-type crystalline silicon substrate 1, an impurity diffusion layer 4 formed on at least a portion of at least one surface of the crystalline silicon substrate 1, a buffer layer 30 formed on at least a portion of a surface of the impurity diffusion layer 4, and an electrode formed on a surface of the buffer layer 30. The electrode of the crystalline silicon solar cell of the present invention contains a conductive metal and a complex oxide 24. The buffer layer 30 formed on at least a portion of the surface of the impurity diffusion layer 4 is a layer containing silicon, oxygen, and nitrogen. Crystalline silicon substrate 1 having the predetermined buffer layer 30 results in a high performance crystalline silicon solar cell.

The buffer layer 30 of the crystalline silicon solar cell of the present invention is preferably a layer containing a conductive metallic element, silicon, oxygen, and nitrogen. To achieve a high performance crystalline silicon solar cell 1, the crystalline silicon substrate preferably has a buffer layer 30 that contains a conductive metallic element in addition to silicon, oxygen, and nitrogen.

In the crystalline silicon solar cell of the present invention, a conductive metallic element to be contained in the buffer layer 30 is preferably silver. Because the electrical resistivity of silver is low, silver can preferably be used as a conductive metallic element to be contained in the buffer layer.

The crystalline silicon solar cell of the present invention includes a buffer layer at at least a portion directly below the electrode. The buffer layer 30 preferably includes a silicon oxynitride film 32 and a silicon oxide film 34 in the recited order from the crystalline silicon substrate 1 toward the light-incident side electrode 20. The phrase “buffer layer 30 directly below the light-incident side electrode 20” means that, as viewed in FIG. 1, if the light-incident side electrode 20 is on the up side and the crystalline silicon substrate 1 is on the down side, the buffer layer 30 lies in contact with the light-incident side electrode 20 on the side of the light-incident side electrode 20 closer to the crystalline silicon substrate 1 (bottom side). The crystalline silicon substrate 1 having the predetermined buffer layer 30 results in a high performance crystalline silicon solar cell. It should be noted that in the crystalline silicon solar cell of the present invention, the buffer layer 30 is formed only directly below the light-incident side electrode 20, and not formed on a portion where the light-incident side electrode 20 does not exist.

The silicon oxynitride film 32 in the buffer layer 30 is specifically a SiOₓN_{y} film. The silicon oxide film 34 of the buffer layer 30 is specifically a SiO_{z} film (generally z=1 to 2). Furthermore, the silicon oxynitride film 32 and the silicon oxide film 34 each have a film thickness of 20-80 nm, preferably 30-70 nm, and more preferably 40-60 nm, and specifically, the thickness can be about 50 nm. Furthermore, the thickness of the buffer layer 30 including the silicon oxynitride film 32 and the silicon oxide film 34 is 40-160 nm, preferably 60-140 nm, more preferably 80-120 nm, and still more preferably 90-110 nm, and specifically, the thickness can be about 100 nm. The silicon oxynitride film 32 and the silicon oxide film 34, as well as the buffer layer 30 including them each have the above-described composition and a thickness within the above-described ranges, whereby a high performance crystalline silicon solar cell can be obtained more reliably.

An unlimited example for forming a buffer layer 30 more reliably is as follows. That is, a buffer layer 30 can be formed by printing the pattern of the light-incident side electrode 20 on the crystalline silicon substrate 1 using a conductive paste that contains a complex oxide containing molybdenum oxide, boron oxide, and bismuth oxide, followed by firing. At this time, the buffer layer 30 can be formed more reliably by printing the pattern of the light-incident side electrode 20, using the conductive paste that contains a complex oxide containing molybdenum oxide, boron oxide, and bismuth oxide, on a surface of an anti-reflection film, which is made of silicon nitride and is formed on a surface of the crystalline silicon substrate 1, followed by firing.

The reason why a high performance crystalline silicon solar cell can be produced by forming a buffer layer 30 at at least a portion directly below the light-incident side electrode 20 is inferred as follows. It should be noted, however, that this inference does not limit the present invention. That is, although the silicon oxynitride film 32 and the silicon oxide film 34 are each an insulating film, these films are believed to be contributing in some way to the electrical contact between the single-crystalline silicon substrate 1 and the light-incident side electrode 20. Furthermore, the buffer layer 30 is believed to play the role of preventing components or impurities (components or impurities that adversely affect the solar cell) in the conductive paste from diffusing into the impurity diffusion layer 4 when the conductive paste is fired. In other words, the buffer layer 30 can prevent adverse effect on the solar cell characteristics at the time of firing to form the electrode. It is therefore inferred that the crystalline silicon solar cell with a structure incorporating a buffer layer 30, which contains silicon oxynitride film 32 and silicon oxide film 34 in the recited order, between the light-incident side electrode 20 and the crystalline silicon substrate 1 and at at least a portion directly below the light-incident side electrode 20 results in high performance crystalline silicon solar cell characteristics.

As stated above, the buffer layer 30 is believed to play the role of preventing components or impurities (components or impurities that adversely affect the solar cell performance) in the conductive paste from diffusing into the impurity diffusion layer 4. Hence, when the types of metals that constitute the conductive powder in the conductive paste are the types of metals that adversely affect the solar cell by diffusing into the impurity diffusion layer 4, such adverse effect on the solar cell characteristics can be prevented because of the presence of the buffer layer 30. For example, copper is more likely to adversely affect the solar cell characteristics than silver by diffusing into the impurity diffusion layer 4. Therefore, when relatively inexpensive copper is used as a conductive powder in the conductive paste, the effect of preventing adverse effect on the solar cell characteristics because of the presence of the buffer layer 30 is more prominent.

The crystalline silicon solar cell of the present invention is preferably such that the impurity diffusion layer 4 is a second conductivity-type impurity diffusion layer 4 formed on the light incident side surface of the first conductivity-type crystalline silicon substrate 1. Furthermore, the electrode of the crystalline silicon solar cell of the present invention preferably is a light-incident side electrode 20 formed on the light incident side surface of the crystalline silicon substrate 1 and has an anti-reflection film 2 made of silicon nitride on at least a portion of the surface of the impurity diffusion layer 4 corresponding to the portion where the electrode is not formed.

When the predetermined buffer layer 30 is formed directly below the light-incident side electrode 20 in the crystalline silicon solar cell, the crystalline silicon solar cell can achieve higher performance. Furthermore, by forming an anti-reflection film 2 made of silicon nitride on the surface where the light-incident side electrode 20 is formed, a buffer layer 30 containing silicon, oxygen, and nitrogen can be formed more reliably.

Furthermore, in the crystalline silicon solar cell of the present invention, the light-incident side electrode 20 preferably includes a finger electrode section for electrically contacting an impurity diffusion layer 4, and a bus bar electrode section for electrically contacting the finger electrode section and a conductive ribbon for taking out current to the outside, and the buffer layer 30 is preferably formed between the finger electrode section and the crystalline silicon substrate 1 and at at least a portion directly below the finger electrode section. The finger electrode section plays the role of collecting current from the impurity diffusion layer 4. Thus, a high performance crystalline silicon solar cell can be produced more reliably by having a structure where the buffer layer 30 is formed directly below the finger electrode section. The bus bar electrode section plays the role of causing the current collected in the finger electrode section to flow to the conductive ribbon. Although it is necessary that the bus bar electrode section has a favorable electrical contact with the finger electrode section and the conductive ribbon, the buffer layer 30 directly below the bus bar electrode section is not necessarily required.

The crystalline silicon solar cell of the present invention preferably has a back surface electrode 15 formed on a back surface of the crystalline silicon substrate 1, opposite from the surface on the light incident side. The crystalline silicon solar cell having a back surface electrode 15 enables taking out of current from the light-incident side electrode 20 and the back surface electrode 15 to the outside.

The crystalline silicon solar cell of the present invention can be aback surface electrode-type crystalline silicon solar cell, in which both negative and positive electrodes are disposed on a back surface. In this case, a predetermined buffer layer 30 is formed directly below the back surface electrode 15. That is, in the back surface electrode-type crystalline silicon solar cell of the present invention, the impurity diffusion layer 4 can consists of a first conductivity-type impurity diffusion layer and a second conductivity-type impurity diffusion layer formed on a back surface of the first conductivity-type crystalline silicon substrate 1, opposite from the surface on the light incident side. The first conductivity-type impurity diffusion layer and the second conductivity-type impurity diffusion layer, each formed in the shape of a comb and disposed to interdigitate with each other. The buffer layer 30 is a buffer layer 30 formed on at least a portion of the surface of the first conductivity-type and second conductivity-type impurity diffusion layers. The electrodes (both negative and positive electrodes) are preferably a first electrode formed on the buffer layer 30 that is formed on at least a portion of the surface of the first conductivity-type impurity diffusion layer, and a second electrode formed on at least a portion of the surface of the second conductivity-type impurity diffusion layer. The first electrode is a positive electrode or a negative electrode, and the second electrode is an electrode having a different polarity from that of the first electrode.

The back surface electrode-type crystalline silicon solar cell of the present invention preferably has a silicon nitride film made of silicon nitride on the back surface of the first conductivity-type crystalline silicon substrate 1 corresponding to a portion where electrodes are not formed and at at least a portion of the impurity diffusion layer(s).

By forming a back surface electrode 15 on the back surface where a silicon nitride film made of silicon nitride is disposed, a buffer layer 30 containing silicon, oxygen, and nitrogen can be formed between the back surface electrode 15 and the crystalline silicon substrate 1 in a reliable manner.

In the crystalline silicon solar cell of the present invention, the buffer layer 30 preferably contains conductive particulates of a conductive metallic element. Because of the conductivity of the conductive particulates, the buffer layer 30 containing the conductive particulates can further reduce the contact resistance between the electrodes and the impurity diffusion layer 4 of the crystalline silicon. This enables to obtain a high performance crystalline silicon solar cell.

The particle size of the conductive particulates contained in the buffer layer 30 of the crystalline silicon solar cell of the present invention is preferably 20 nm or less, more preferably 15 nm or less, and still more preferably 10 nm or less. The conductive particulates contained in the buffer layer 30 having a predetermined particle size allows the conductive particulates to be stably present within the buffer layer 30. This enables further reduction in the contact resistance between the light-incident side electrode 20 and the impurity diffusion layer 4 of the crystalline silicon substrate 1.

In the crystalline silicon solar cell of the present invention, the conductive particulates preferably be present only in the silicon oxide film 34 of the buffer layer 30. It is inferred that the conductive particulates being present only in the silicon oxide film 34 of the buffer layer 30 contributes to a higher performance crystalline silicon solar cell. Thus, the conductive particulates are preferably not present in the silicon oxynitride film 32 but present only in the silicon oxide film 34.

The conductive particulates contained in the buffer layer 30 of the crystalline silicon solar cell of the present invention are preferably silver particulates 36. When silver powder is used as a conductive powder in producing a crystalline silicon solar cell, silver particulates 36 serve as the conductive particulates within the buffer layer 30. As a result, a highly reliable, high performance crystalline silicon solar cell can be obtained.

The area of the buffer layer 30 of the crystalline silicon solar cell of the present invention is 5% or more, and preferably 10% or more of the area directly below the crystalline silicon substrate 1. As stated above, by having a buffer layer 30 at at least a portion directly below the light-incident side electrode 20 of crystalline silicon solar cell, a high performance crystalline silicon solar cell can be produced. When the area of the buffer layer 30 being present directly below the light-incident side electrode 20 accounts for a predetermined percentage or more, a high performance crystalline silicon solar cell can be obtained more reliably.

The electrodes (the light-incident side electrode 20 and the back surface electrode 15) of the crystalline silicon solar cell of the present invention contain silver 22 and complex oxide 24. The complex oxide 24 preferably contains molybdenum oxide, boron oxide, and bismuth oxide. The electrodes of the crystalline silicon solar cell of the present invention can be obtained by firing a conductive paste containing a complex oxide that contains molybdenum oxide, boron oxide, and bismuth oxide. As a result of the complex oxide 24 containing the three components of molybdenum oxide, boron oxide, and bismuth oxide, the structure of a high performance crystalline silicon solar cell of the present invention can be obtained more reliably.

The complex oxide 24 contained in the electrodes of the crystalline silicon solar cell of the present invention preferably contains 25-65 mol % of molybdenum oxide, 5-45 mol % of boron oxide, and 25-35 mol % of bismuth oxide when the total of molybdenum oxide, boron oxide, and bismuth oxide is taken as 100 mol %.

The complex oxide 24 having a predetermined composition ensures a favorable electrical contact with low contact resistance between the electrode and the impurity diffusion layer of the predetermined crystalline silicon solar cell without adversely affecting the solar cell characteristics.

Although the descriptions above are mainly of an example where a p-type crystalline silicon substrate 1 was used as a crystalline silicon substrate 1 in the case of the crystalline silicon solar cell as shown in FIG. 1, an n-type crystalline silicon substrate 1 can be used as a substrate for the crystalline silicon solar cell. In that case, a p-type impurity diffusion layer 4 is disposed as an impurity diffusion layer 4 instead of an n-type impurity diffusion layer 4. An electrode with low contact resistance can be formed on any of a p-type impurity diffusion layer 4 and an n-type impurity diffusion layer 4, by using the conductive paste of the present invention.

Although the above description was given for the production of a crystalline silicon solar cell as an example, the present invention is also applicable to the formation of an electrode for devices other than solar cells. For example, the above-described conductive paste of the present invention may be used as a conductive paste for forming an electrode for devices, other than solar cells, using a typical crystalline silicon substrate 1.

The present invention is a method for producing a crystalline silicon solar cell that uses the above-described conductive paste. Hereinbelow, a method for producing a crystalline silicon solar cell of the present invention will be described.

FIG. 1 shows a schematic cross-sectional view around a light-incident side electrode 20 of a crystalline silicon solar cell that has an electrode on both the light incident side and the back surface side (a light-incident side electrode 20 and a back surface electrode 15). Referring to a crystalline silicon solar cell of the structure shown in FIG. 1 as an example, a method for producing a crystalline silicon solar cell of the present invention will be described.

A method for producing a crystalline silicon solar cell of the present invention includes the steps of preparing a first conductivity-type crystalline silicon substrate 1; forming an impurity diffusion layer 4 on at least a portion of at least one surface of the crystalline silicon substrate 1; forming a silicon nitride film on a surface of the impurity diffusion layer 4; printing a conductive paste on a surface of the silicon nitride film formed on the impurity diffusion layer 4, followed by firing, to form an electrode, while simultaneously forming a buffer layer 30 between the electrode and the impurity diffusion layer 4. The buffer layer 30 is a layer containing silicon, oxygen, and nitrogen.

In the example of the crystalline silicon solar cell shown in FIG. 1, the impurity diffusion layer 4 is a second conductivity-type impurity diffusion layer 4 formed on the light incident side surface of a first conductivity-type crystalline silicon substrate 1, and the electrode is a light-incident side electrode 20 formed on the light incident side surface of the crystalline silicon substrate 1. The production method according to the present invention can be preferably used for producing a crystalline silicon solar cell with the structure as shown in FIG. 1. When the predetermined buffer layer 30 is formed directly below the light-incident side electrode 20 in the crystalline silicon solar cell, a higher performance crystalline silicon solar cell can be obtained. Furthermore, by forming a light-incident side electrode 20 on the surface where an anti-reflection film 2 made of silicon nitride is disposed, a buffer layer 30 containing silicon, oxygen, and nitrogen can be formed more reliably.

In a method for producing a crystalline silicon solar cell of the present invention, the light-incident side electrode 20 preferably includes a finger electrode section for electrically contacting the impurity diffusion layer 4, and a bus bar electrode section for electrically contacting the finger electrode section and a conductive ribbon for taking out current to the outside. Furthermore, the buffer layer 30 is preferably formed between the finger electrode section and the crystalline silicon substrate 1, and at at least a portion directly below the finger electrode section. The finger electrode section plays the role of collecting current from the impurity diffusion layer 4. Thus, with the structure where the buffer layer is formed directly below the finger electrode section, a high performance crystalline silicon solar cell can be obtained more reliably. The bus bar electrode section plays the role of causing the current collected in the finger electrode section to flow to the conductive ribbon. Although it is necessary that the bus bar electrode section has a favorable electrical contact with the finger electrode section and the conductive ribbon, the buffer layer 30 directly below the bus bar electrode section is not necessarily required.

A method for producing a crystalline silicon solar cell of the present invention includes the step of preparing a first conductivity-type crystalline silicon substrate 1. As the crystalline silicon substrate 1, for example, a B-doped (boron-doped) p-type single-crystalline silicon substrate may be used.

In view of achieving high conversion efficiency, the surface of the light incident side of a crystalline silicon substrate 1 preferably has pyramid-like texture structures.

Next, the method for producing a crystalline silicon solar cell of the present invention includes the step of forming an impurity diffusion layer 4 on at least a portion of at least one surface of the crystalline silicon substrate 1 prepared in the above-described step.

For example, when a p-type single-crystalline silicon substrate is used as the crystalline silicon substrate 1, an n-type impurity diffusion layer 4 can be formed as an impurity diffusion layer 4. The impurity diffusion layer 4 may be formed so that the sheet resistance is 60-140 Ω/square, and preferably 80-120 Ω/square. In the method for producing a crystalline silicon solar cell of the present invention, a buffer layer 30 is formed in the subsequent step. The presence of the buffer layer 30 is believed to prevent the components or impurities (components or impurities that adversely affect the solar cell) in the conductive paste from diffusing into the impurity diffusion layer 4 when the conductive paste is fired. Hence, in the crystalline silicon solar cell of the present invention, even when the impurity diffusion layer 4 is thinner (higher sheet resistance) than a conventional impurity diffusion layer 4, an electrode with low contact resistance can be formed on a crystalline silicon substrate 1 without adversely affecting the solar cell characteristics. Specifically, in the method for producing a crystalline silicon solar cell of the present invention, the depth for forming the impurity diffusion layer 4 may be 150 nm-300 nm. Here, the depth of the impurity diffusion layer 4 indicates the depth measured from the surface of the impurity diffusion layer 4 to the p-n junction. The depth of the p-n junction may be the depth measured from the surface of the impurity diffusion layer 4 to the depth where the impurity density of the impurity diffusion layer 4 reaches 10¹⁶ cm⁻³.

Next, the method for producing a crystalline silicon solar cell of the present invention includes the step of forming a silicon nitride film on the surface of the impurity diffusion layer 4.

As the anti-reflection film 2, a silicon nitride film (SiN film) may be formed. When a silicon nitride film is used as an anti-reflection film 2, the silicon nitride film also serves as a surface passivation film. Thus, when the silicon nitride film is used as an anti-reflection film 2, a high performance crystalline silicon solar cell can be obtained. The silicon nitride film may be formed by the Plasma Enhanced Chemical Vapor Deposition (PECVD) method.

Next, the method for producing a crystalline silicon solar cell of the present invention includes the step of printing a conductive paste on the surface of the silicon nitride film, which is formed on the surface of the impurity diffusion layer 4, followed by firing so as to form an electrode and a buffer layer 30 between the electrode and the impurity diffusion layer 4. The conductive paste preferably used in the method for producing a crystalline silicon solar cell of the present invention will be described later.

Specifically, first, an electrode pattern printed by using a conductive paste of the present invention is dried at a temperature of around 100-150° C. for a few minutes (e.g., 0.5-5 min). Here, at this time, a conductive paste for the predetermined back surface electrode 15 is preferably also printed on substantially the entire surface of a back surface of the crystalline silicon substrate 1, opposite from the surface on the light incident side, for the formation of the back surface electrode 15, followed by drying.

Subsequently, the dried conductive paste is fired in the air using a firing furnace, such as a tubular furnace, under the same conditions as those of the above-described firing conditions. In this case as well, the firing temperature is 400-850° C., and preferably 450-820° C. At the time of firing, a conductive paste for forming a light-incident side electrode 20 and a conductive paste for forming a back surface electrode 15 are fired simultaneously to form both electrodes simultaneously.

At the time the conductive paste printed on the surface of the silicon nitride film, which is formed on the surface of the impurity diffusion layer 4, is fired, a buffer layer 30 is formed. When the conductive paste is fired, the silicon nitride film reacts with the conductive paste to produce a buffer layer 30, which contains silicon, oxygen, and nitrogen.

The buffer layer 30 is preferably a layer containing a conductive metallic element in addition to silicon, oxygen, and nitrogen. A high performance crystalline silicon solar cell can be produced by forming a buffer layer 30 containing a conductive metallic element.

The conductive metallic element contained in the buffer layer 30 is preferably silver. Silver can preferably be used as a conductive metallic element to be contained in the buffer layer because the electrical resistivity of silver is low.

According to the above-described production method, a crystalline silicon solar cell of the present invention incorporating the predetermined buffer layer 30 can be produced. According to the method for producing a crystalline silicon solar cell of the present invention, an electrode with low contact resistance (a light-incident side electrode 20) with an impurity diffusion layer 4 particularly in which n-type impurities are diffused (an n-type impurity diffusion layer 4), can be produced without adversely affecting the solar cell characteristics.

Specifically, according to the above-described method for producing a crystalline silicon solar cell using the conductive paste of the present invention, a crystalline silicon solar cell having an electrode with a contact resistance of 350 mΩ·cm² or less, preferably 100 mΩ²·cm or less, more preferably 25 mΩ·cm² or less, and still more preferably 10 mΩ·cm² or less can be produced. In general, when the contact resistance of an electrode is 100 mΩ·cm² or less, the electrode may be used as an electrode for a single-crystalline silicon solar cell. Furthermore, when the contact resistance of an electrode is 350 mΩ·cm² or less, the electrode may be used as an electrode for a crystalline silicon solar cell. However, when the contact resistance exceeds 350 mΩ·cm², it is difficult to use the electrode as an electrode for a crystalline silicon solar cell. By forming an electrode using a conductive paste of the present invention, a crystalline silicon solar cell with favorable performance can be produced.

In the above description, like the crystalline silicon solar cell shown in FIG. 1, a crystalline silicon solar cell including a buffer layer 30 on at least a portion directly below the light-incident side electrode 20 is used as an example for illustration. The present invention, however, is not limited to this. The method for producing a crystalline silicon solar cell of the present invention is applicable to produce a crystalline silicon solar cell having both positive and negative electrodes (a back surface electrode-type crystalline silicon solar cell) on the back surface of a crystalline silicon solar cell.

In the method for producing a back surface electrode-type crystalline silicon solar cell of the present invention, first, a first conductivity-type crystalline silicon substrate 1 is prepared. Next, a first conductivity-type impurity diffusion layer and a second conductivity-type impurity diffusion layer are formed on the back surface of the first conductivity-type crystalline silicon substrate, opposite from the surface on the light incident side. At this time, the first conductivity-type impurity diffusion layer and the second conductivity-type impurity diffusion layer, each formed in the shape of a comb and disposed to interdigitate with each other. Next, a silicon nitride film is formed on the surface of the impurity diffusion layers (i.e., the back surface). Next, a conductive paste is printed on at least a portion of the surface of the anti-reflection film 2 corresponding to a region where the first conductivity-type and second conductivity-type impurity diffusion layers are formed, followed by firing. As a result, a first electrode is formed on at least a portion of the surface of the buffer layer 30 formed on at least a portion of the surface of the first conductivity-type impurity diffusion layer, and a second electrode is formed on the surface of the buffer layer 30 formed on at least a portion of the surface of the second conductivity-type impurity diffusion layer. According to the above-described steps, a back surface electrode-type crystalline silicon solar cell can be produced. The firing of the conductive paste is conducted under the same conditions as the method for producing a crystalline silicon solar cell including a buffer layer 30 at at least a portion directly below the light-incident side electrode 20.

Here, in the method for producing the above-described back surface electrode-type crystalline silicon solar cell, when forming a silicon nitride film, it is preferable to form a silicon nitride film made of silicon nitride at least a portion of the back surface of the first conductivity-type crystalline silicon substrate 1 and the impurity diffusion layers corresponding to the portion where the electrodes are not formed. By forming a back surface electrode 15 on the back surface where the silicon nitride film made of silicon nitride is formed, a buffer layer 30 containing silicon, oxygen, and nitrogen can be formed in a more reliable manner between the back surface electrode 15 and the crystalline silicon substrate 1.

According to the above-described method for producing a crystalline silicon solar cell of the present invention, at least a portion of the buffer layer 30 can have a structure where a silicon oxynitride film 32 and a silicon oxide film 34 are formed in the recited order from the crystalline silicon substrate 1 toward the light-incident side electrode 20. A buffer layer 30 of the predetermined structure in a crystalline silicon solar cell ensures production of a high performance crystalline silicon solar cell.

Next, a conductive paste that can be preferably used in the method for producing a crystalline silicon solar cell of the present invention (hereinafter referred to as “conductive paste of the present invention”) will be described.

The conductive paste of the present invention is a conductive paste for forming electrodes for a crystalline silicon solar cell, containing an electrically conductive powder, a complex oxide, and an organic vehicle. The complex oxide of the conductive paste of the present invention contains molybdenum oxide, boron oxide, and bismuth oxide. By using a conductive paste of the present invention for forming an electrode of a semiconductor device, such as a crystalline silicon solar cell, an electrode with low contact resistance with a crystalline silicon substrate can be formed without adversely affecting the solar cell characteristics.

The conductive paste of the present invention contains a conductive powder. As the conductive powder, a metallic powder of any single element or alloy may be used. As the metallic powder, for example, a metallic powder containing at least one selected from the group consisting of silver, copper, nickel, aluminum, zinc and tin may be used. As the metallic powder, a metallic powder of a single element, an alloy powder of these metals or the like may be used.

As the conductive powder contained in the conductive paste of the present invention, it is preferable to use a conductive powder containing at least one from the group selected from silver, copper, and an alloy thereof. Among these, in particular, it is more preferable to use a conductive powder containing silver. Copper powder is relatively inexpensive and has high conductivity, so that it is preferable as a material for an electrode. Furthermore, silver powder has high conductivity and has conventionally been used as an electrode in many crystalline silicon solar cells and is highly reliable. In the conductive paste of the present invention as well, by using, in particular, silver powder as a conductive powder, a highly reliable and high performance crystalline silicon solar cell can be produced. Thus, it is preferable to use silver powder as a main component of the conductive powder. Additionally, the conductive paste of the present invention may contain other metallic powder in addition to silver powder or contain an alloy powder with silver within a range not to impair the performance of the solar cell electrode. To achieve low electrical resistance and high reliability, however, the conductive powder contains preferably 80 wt % or more, more preferably 90 wt % or more of silver powder relative to the total conductive powder, and, still more preferably, the conductive powder is composed of silver powder.

The shape and size of the particles of the conductive powder, such as silver powder, are not particularly limited. As the shape of the particles, for example, a spherical shape and a scale-like shape may be used. The particle size refers to a size of a portion that has the longest length in a particle. In view of workability or the like, the particle size of the conductive powder is preferably 0.05-20 μm, and more preferably 0.1-5 μm.

In general, because a large number of microparticles has a given distribution, not all the particles need to have the above-described particle size. The particle size of 50% of the integrated value of all the particles preferably has a particle size within the above-described range (mean particle size: D50). The same can be said about the particle size of the particles other than the conductive powder as described herein. Furthermore, the mean particle size can be determined by measuring particle size distribution using the micro-track method (Laser diffraction scattering method), and calculating the D50 value from the results of the particle size distribution measurement.

Furthermore, the size of the conductive powder, such as silver powder, can be expressed by a BET value (BET specific surface area). The BET value of the conductive powder is preferably 0.1-5 m²/g and more preferably 0.2-2 m²/g.

The conductive paste of the present invention contains a complex oxide containing molybdenum oxide, boron oxide, and bismuth oxide. The complex oxide contained in the conductive paste of the present invention may be a complex oxide in the form of particles, i.e., in the form of a glass frit.

FIG. 2 is an illustrating view based on the ternary composition diagram of a ternary glass containing molybdenum oxide, boron oxide, and bismuth oxide, which is described in Non-Patent Document 1 (R. Iordanova, et al., Journal of Non-Crystalline Solids, 357 (2011) pp. 2663-2668). The vitrifiable compositions of a glass containing molybdenum oxide, boron oxide, and bismuth oxide are in the region referred to as “Vitrifiable region” in FIG. 2, i.e., the grey-colored composition region. Complex oxides of the compositions in the composition region referred to as the “Unvitrifiable region” in FIG. 2 are unvitrifiable, so that a complex oxide of such a composition cannot exist as a glass. Therefore, the complex oxide containing molybdenum oxide, boron oxide, and bismuth oxide that can be used in the conductive paste of the present invention is a complex oxide of a composition within the “vitrifiable region” in FIG. 2. The complex oxide containing boron oxide and bismuth oxide has a glass-transition point of around 380-420° C. and a melting point of around 420-540° C. although they vary depending on the composition.

The complex oxide contained in the conductive paste of the present invention is preferably of a composition within the composition range containing, when the total of molybdenum oxide, boron oxide, and bismuth oxide is taken as 100 mol %, 25-65 mol % of molybdenum oxide, 5-45 mol % of boron oxide, and 25-35 mol % of bismuth oxide. In FIG. 2, this composition range is indicated as the composition range of Region 1. Setting the composition range of molybdenum oxide, boron oxide, and bismuth oxide to the composition range of Region 1 ensures a favorable electrical contact with low contact resistance between a light-incident side electrode and an impurity diffusion layer of the predetermined crystalline silicon solar cell without adversely affecting the solar cell characteristics.

To further lower the contact resistance between the predetermined light-incident side electrode and the impurity diffusion layer of the crystalline silicon solar cell, molybdenum oxide in the complex oxide can be more preferably 35-65 mol %, still more preferably 40-60 mol % within the composition range of Region 1 in FIG. 2. Furthermore, for the same reason, bismuth oxide in the complex oxide can be more preferably 28-32 mol % within the composition range of Region 1 in FIG. 2.

The complex oxide contained in the conductive paste of the present invention is preferably of a composition within the composition range containing, when the total of molybdenum oxide, boron oxide, and bismuth oxide is taken as 100 mol %, 15-40 mol % of molybdenum oxide, 25-45 mol % of boron oxide, and 25-60 mol % of bismuth oxide. In FIG. 2, this composition range is indicated as the composition range of Region 2. Setting the composition range of molybdenum oxide, boron oxide, and bismuth oxide to the composition range of Region 2 ensures a favorable electrical contact with low contact resistance between the predetermined light-incident side electrode of the crystalline silicon solar cell and the impurity diffusion layer without adversely affecting the solar cell characteristics.

To further lower the contact resistance between a light-incident side electrode and an impurity diffusion layer of the predetermined crystalline silicon solar cell, molybdenum oxide in the complex oxide can preferably be 20-40 mol % in the composition range of Region 2 in FIG. 2. Furthermore, for the same reason, the boron oxide in the complex oxide can preferably be 20-40 mol % within the composition range in Region 2 in FIG. 2.

The complex oxide contained in the conductive paste of the present invention preferably contains 90 mol % or more, preferably 95 mol % or more of molybdenum oxide, boron oxide, and bismuth oxide in total relative to 100 mol % of the complex oxide. Containing the three components: molybdenum oxide, boron oxide, and bismuth oxide not less than the predetermined percentage ensures a favorable electrical contact with low contact resistance between the predetermined light-incident side electrode of the crystalline silicon solar cell and the impurity diffusion layer.

The complex oxide contained in the conductive paste of the present invention preferably further contains 0.1-6 mol %, preferably 0.1-5 mol % of titanium oxide relative to 100 mol % of the complex oxide. The complex oxide further containing the predetermined percentage of titanium oxide leads to further preferable electrical contact.

The complex oxide contained in the conductive paste of the present invention preferably further contains 0.1-3 mol %, preferably 0.1-2.5 mol % of zinc oxide relative to 100 mol % of the complex oxide. The complex oxide further containing the predetermined percentage of zinc oxide leads to a more favorable electrical contact.

The conductive paste of the present invention can contain preferably 0.1-10 parts by weight, more preferably 0.5-8 parts by weight of a complex oxide, relative to 100 parts by weight of the conductive powder. When a large amount of a non-conductive complex oxide is present in an electrode, the electrical resistance of the electrode increases. The amount of the complex oxide in the conductive paste of the present invention being within the predetermined range can suppress increase in the electrical resistance of the electrode to be formed.

The complex oxide in the conductive paste of the present invention may contain any oxide, in addition to the above-described oxide, within a range not to impair the predetermined performance of the complex oxide. For example, the complex oxide of a conductive paste of the present invention may contain an oxide selected from Al₂O₃, P₂O₅, CaO, MgO, ZrO₂, Li₂O₃, Na₂O₃, CeO₂, SnO₂, SrO, or the like as appropriate.

The shape of the particles of the complex oxide is not limited. For example, a spherical shape, a non-uniform shape etc. may be used. Furthermore, the particle size is not particularly limited, either. In view of workability or the like, the mean value (D50) of the particle size is preferably in the range of 0.1-10 μm, and more preferably in the range of 0.5-5 μm.

The complex oxide contained in the conductive paste of the present invention may be produced, for example, by the following method.

First, powders of oxides as materials are weighed, mixed, and put into a crucible. The crucible is placed into a heated oven, and the temperature (of the content in the crucible) is raised to a melting temperature, and the melting temperature is maintained until the materials are fully melted. Next, the crucible is taken out of the oven, the melted content is uniformly stirred, and the content of the crucible is quenched with two rolls of stainless-steel to yield a plate-like glass. Finally, the plate-like glass is uniformly dispersed while being pounded in a mortar, and sifted through a mesh sieve to obtain a complex oxide having a desired particle size. By sifting what is left on a 200-mesh sieve after the sifting through a 100-mesh sieve, a complex oxide having a mean particle size of 149 μm (median size, D50) can be obtained. Furthermore, the size of the complex oxide is not limited to the above examples, and a complex oxide having a larger mean particle size or a smaller mean particle size may be produced depending on the size of the mesh sieve. By further pulverizing the complex oxide, a complex oxide of a predetermined mean particle size (D50) can be obtained.

The conductive paste of the present invention contains an organic vehicle.

As the organic vehicle to be contained in the conductive paste of the present invention, an organic binder and a solvent can be contained. The organic binder and the solvent serve as a viscosity modifier or the like of the conductive paste, and none of them is particularly limited. An organic binder may be dissolved into a solvent before use.

The organic binder may be selected from cellulosic resins (e.g., ethyl cellulose, nitrocellulose), (meth)acrylic resins (e.g., polymethylacrylate, polymethylmethacrylate). The amount of the organic binder to be added is typically 0.2-30 parts by weight, and preferably 0.4-5 parts by weight relative to 100 parts by weight of the conductive powder.

As the solvent, one or two or more may be selected from alcohols (e.g., terpineol, α-terpineol, β-terpineol) and esters (e.g., hydroxy group-containing esters, 2,2,4-trimethyl-1,3-pentanediol monoisobutyrate, butyl carbitol acetate). The amount of the solvent to be added is typically 0.5-30 parts by weight, and preferably 5-25 parts by weight relative to 100 parts by weight of the conductive powder.

Into the conductive paste of the present invention, an additive selected from, for example, a plasticizer, an antifoamer, a dispersant, a leveling agent, a stabilizer, and an accelerator may further be blended as necessary. Among these, a plasticizer selected from, for example, phthalate esters, glycolate esters, phosphate esters, sebacate esters, adipate esters, and citrate esters may be used.

Next, a method for producing a conductive paste of the present invention will be described.

The method for producing a conductive paste of the present invention includes the step of mixing a conductive powder, a complex oxide, and an organic vehicle. A conductive paste of the present invention can be produced by adding to an organic binder and a solvent, a conductive powder, the above-described complex oxide, and, optionally, other additives and addition particles, followed by mixing and dispersing.

Mixing may be performed using, for example, a planetary mixer. Furthermore, dispersing may be performed using a three-roll mill. Mixing and dispersing are not limited to these methods, and many known methods may be used.

### EXAMPLES

Hereinafter, the present invention will be specifically described with reference to Examples, but the present invention is not limited to these Examples.

As Experiment 1, single-crystalline silicon solar cells were produced experimentally using conductive pastes that can be used for a single-crystalline silicon solar cell of the present invention (conductive pastes of the present invention), and the solar cell characteristics were measured. Furthermore, as Experiment 2, an electrode for measuring contact resistance was produced using conductive pastes of the present invention, and the contact resistance between the formed electrode and the impurity diffusion layer 4 of the single-crystalline silicon substrate was measured to determine whether or not the conductive paste of the present invention can be used. Furthermore, as Experiment 3, a cross-sectional shape of the experimentally produced single-crystalline silicon solar cell was observed using a scanning electron microscope (SEM) and a transmission electron microscope (TEM) to clarify the structure of the crystalline silicon solar cell of the present invention. Furthermore, by Experiments 4 to 6, the electrical characteristics of single-crystalline silicon solar cells that were produced using conductive pastes of the present invention were evaluated.

<Materials of Conductive Paste and their Preparation Ratio>

The composition of the conductive paste used for the experimental production of the single-crystalline silicon solar cell of Experiment 1 and for the production of the electrode for the measurement of contact resistance of Experiment 2 are as follows.
Conductive powder: Powder of Ag (100 parts by weight) having a spherical shape, a BET value of 1.0 m²/g, and a mean particle size (D50) of 1.4 μm was used.
Organic binder: An organic binder of ethyl cellulose (2 parts by weight) having an ethoxy content of 48-49.5 wt % was used.
Plasticizer: Oleic acid (0.2 parts by weight) was used.
Solvent: Butyl carbitol (5 parts by weight) was used.
Complex oxide: Types of the complex oxides (glass frits) (A1, A2, B1, B2, C1, C2, D1, and D2) used for the production of single-crystalline silicon solar cells of Examples 1 and 2 and Comparative Examples 1-6 are shown in Table 1. Specific compositions of complex oxides (glass frits) A1, A2, D1 and D2 are shown in Table 2. The weight percentage of the complex oxide in each conductive paste was set to 2 parts by weight. Furthermore, complex oxides in the form of a glass frit were used. The mean particle size D50 of the glass flit was 2 μm. In the present Examples, a complex oxide may also be referred to as a glass frit.

The method for producing a complex oxide is as follows.

Oxide powders (glass frit components) as materials shown in Table 1 were each weighed, mixed, and put into a crucible. Table 2 shows examples of specific mixing ratio of complex oxides (glass frits) A1, A2, D1 and D2. Each crucible was put into a heated oven and the temperature (of the content in the crucible) was raised to a melting temperature, and the melting temperature was maintained until the materials were fully melted. Next, the crucible was taken out of the oven, the melted content was stirred uniformly, and the content of the crucible was quenched with two rolls of stainless-steel to obtain a plate-like glass. Finally, the plate-like glass was uniformly dispersed while being pounded in a mortar, and sifted through a mesh sieve to obtain a complex oxide having a desired particle size. By sifting what is left on a 200-mesh sieve after the sifting through a 100-mesh sieve, a complex oxide having a mean particle size of 149 μm (median size, D50) was obtained. Furthermore, each complex oxide was further pulverized to obtain a complex oxide having a mean particle size D50 of 2 μm.

Next, the above-described materials, such as a conductive powder and a complex oxide, were used to produce a conductive paste. Specifically, materials of the above-described predetermined preparation ratio were mixed using a planetary mixer, dispersed using a three-roll mill, and formed into a paste to obtain a conductive paste.

### Experiment 1

### Test Product of Single-Crystalline Silicon Solar Cell

As Experiment 1, single-crystalline silicon solar cells were produced experimentally using the respective prepared conductive pastes, and the characteristics were measured to evaluate the conductive pastes of the present invention. The method of producing a test product of a single-crystalline silicon solar cell is as follows.

As the substrate, a B-doped (boron-doped) p-type single-crystalline silicon substrate (substrate with a thickness of 200 μm) was used.

First, on the substrate, a silicon oxide layer of about 20 μm was formed by dry oxidation, and etching was performed with a solution prepared by mixing hydrogen fluoride, pure water, and ammonium fluoride, to remove damage on the surface of the substrate. Furthermore, heavy metals were washed off with an aqueous solution containing hydrochloric acid and hydrogen peroxide.

Next, a texture (surface roughness) was formed on a surface of this substrate by wet etching. Specifically, pyramid like texture structures were formed on one surface (light incident side surface) of the substrate by a wet etching method (an aqueous solution of sodium hydroxide). Subsequently, washing was performed with an aqueous solution containing hydrochloric acid and hydrogen peroxide.

Next, phosphorus was diffused by a diffusion method using phosphorus oxychloride (POCl₃) on the surface of the substrate having the above-described texture structures at a temperature of 810° C. for 30 minutes in a manner to yield an n-type impurity diffusion layer 4 having a depth of about 0.28 μm. The sheet resistance of the n-type impurity diffusion layer 4 was 100 Ω/square.

Next, on the surface of the substrate on which the n-type impurity diffusion layer 4 was formed, a silicon nitride thin-film (anti-reflection film 2) with a thickness of about 60 nm was formed by the plasma chemical vapor deposition (CVD) method using silane gas and ammonia gas. Specifically, a mixed gas of NH₃/SiH₄=0.5 at 1 Torr (133 Pa) was decomposed by the glow discharge to yield a silicon nitride thin-film (anti-reflection film 2) with a film thickness of about 60 nm using the plasma CVD method.

The thus obtained single-substrate for the crystalline silicon solar cell was cut into squares of 15 mm×15 mm before use.

Printing of a conductive paste for a light incident side (surface) electrode was performed by screen printing. On the anti-reflection film 2 of the substrate, a pattern of a bus bar electrode section with a width of 2 mm and a finger electrode section consisting of six fingers with a length of 14 mm and a width of 100 μm was printed, followed by drying at 150° C. for about 60 seconds.

Next, printing of a conductive paste for a back surface electrode 15 was performed by screen printing. A conductive paste mainly composed of aluminum particles, a complex oxide, ethyl cellulose, and a solvent was printed on the back surface of the substrate in the form of a 14 mm-square, and dried at 150° C. for about 60 seconds. The film thickness of the conductive paste for the back surface electrode 15 after drying was about 20 μm.

The substrate prepared by printing a conductive paste on a top surface and a back surface as described above was fired using a near-infrared firing furnace with a halogen lamp as a source of heat (a high speed firing furnace for solar cells manufactured by DESPATCH) in the air under predetermined conditions. The firing conditions are as follows: both surfaces were simultaneously fired at a peak temperature of 800° C. in the air by putting the substrate in and out of the furnace for 60 seconds. As stated above, a single-crystalline silicon solar cell was produced experimentally.

<Measurement of Solar Cell Characteristics>

The electrical properties of the solar cells were measured as follows. That is, current-voltage characteristics of the experimentally produced single-crystalline silicon solar cells were measured under the irradiation of solar simulator light (AM 1.5, energy density of 100 mW/cm²). From the results of measurements, fill factor (FF), open circuit voltage (Voc), short-circuit current (Jsc) and conversion efficiency η (%) were calculated. Two samples of the same conditions were prepared, and the measurement value was determined as a mean value of the two samples.

<Results of Measurements of Solar Cell Characteristics in Experiment 1>

Conductive pastes of Examples 1 and 2 and Comparative Examples 1-6 containing the complex oxides (glass frits) shown in Tables 1 and 2 were prepared. These conductive pastes were each used for the formation of a light-incident side electrode 20 of a single-crystalline silicon solar cell, so that single-crystalline silicon solar cells of Experiment 1 were produced experimentally in a manner described above. Table 3 shows the characteristics of these single-crystalline silicon solar cells, specifically, the results of measurements of fill factor (FF), open circuit voltage (Voc), short-circuit current (Jsc) and conversion efficiency η (%). Furthermore, Suns-Voc of these single-crystalline silicon solar cells were measured, and recombination current (J₀₂) was measured. The method for measuring Suns-Voc and the method for calculating recombination current J₀₂ from the results of measurements are known.

As is clear from Table 3, the characteristics of the single-crystalline silicon solar cells of Comparative Examples 1-6 were lower than those of the single-crystalline silicon solar cells of Examples 1 and 2. In particular, the fill factor (FF) was high in the single-crystalline silicon solar cells of Examples 1 and 2. This indicates that in the single-crystalline silicon solar cells of Examples 1 and 2, the contact resistance between the light-incident side electrode 20 and the impurity diffusion layer 4 of the single-crystalline silicon substrate was low. Furthermore, in the single-crystalline silicon solar cells of Examples 1 and 2, open circuit voltage (Voc) was high compared to Comparative Examples 1-6. These facts indicate that the surface recombination rate of the carriers was low in the single-crystalline silicon solar cells of Examples 1 and 2 compared to Comparative Examples 1-6. Furthermore, the recombination current J₀₂ was low in the single-crystalline silicon solar cells of Examples 1 and 2 compared to Comparative Examples 1-6. These facts indicate that the recombination rate of the carriers in the depletion layer of the p-n junction within the single-crystalline silicon solar cells of Examples 1 and 2 is low. That is, it is indicated that in the single-crystalline silicon solar cells of Examples 1 and 2, the recombination level density, which is attributable to the diffusion of impurities or the like contained in the conductive paste, around the p-n junction is low compared to Comparative Examples 1-6.

As stated above, it has been revealed that when a conductive paste of the present invention is used in forming a light-incident side electrode 20 on a surface that has an anti-reflection film 2 made of a silicon nitride thin-film or the like in a single-crystalline silicon solar cell, the contact resistance between the light-incident side electrode 20 and the emitter layer is low, so that a favorable electrical contact can be achieved. This suggests that using a conductive paste of the present invention in forming an electrode on a surface of a typical crystalline silicon substrate 1 results in the formation of an electrode with a favorable electrical contact.

### Experiment 2

### Preparation of an Electrode for the Measurement of Contact Resistance

In Experiment 2, conductive pastes of the present invention containing a complex oxide of different composition were each used to form an electrode on a surface, where an impurity diffusion layer 4 is disposed, of a crystalline silicon substrate 1, and each contact resistance was measured. Specifically, the pattern for measuring contact resistance using a conductive paste of the present invention, was screen-printed on a single-crystalline silicon substrate with a predetermined impurity diffusion layer 4, dried and fired to yield an electrode for measuring contact resistance. Table 4 shows the compositions of the complex oxides (glass frits) in the conductive pastes used in Experiment 2 as Samples a to g. Furthermore, the compositions corresponding to the complex oxides (glass frits) of Samples a to g are shown on the ternary composition diagram of three oxides in FIG. 2. The method for preparing an electrode for measuring contact resistance is as follows.

Like the test products of the single-crystalline silicon solar cells of Experiment 1, a B-doped (boron-doped) p-type single-crystalline silicon substrate (substrate thickness of 200 μm) was used as a substrate, and the damage on the surface of the substrate was removed and heavy metals were washed off.

Next, a texture (surface roughness) was formed on the surface of the substrate by wet etching. Specifically, pyramid-like texture structures were formed on one surface (light incident side surface) by the wet etching method (aqueous solution of sodium hydroxide). Subsequently, washing was performed using an aqueous solution containing hydrochloric acid and hydrogen peroxide.

Next, like the test products of the single-crystalline silicon solar cells of Experiment 1, phosphorus was diffused by a diffusion method using phosphorus oxychloride (POCl₃) on the surface of the substrate at a temperature of 810° C. for 30 minutes in a manner to yield an n-type impurity diffusion layer 4 having a sheet resistance of 100 Ω/square. The thus obtained substrate for the measurement of contact resistance was used for the preparation of an electrode for measuring contact resistance.

Printing of the conductive paste for the measurement of contact resistance on a substrate was performed by screen printing. A pattern for measuring contact resistance was printed on the above-described substrate such that the film thickness was about 20 μm, and then dried at 150° C. for about 60 seconds. As shown in FIG. 7, the pattern for measuring contact resistance was a pattern in which five rectangular electrode patterns each having a width of 0.5 mm and a length of 13.5 mm were arranged such that they are spaced apart at an interval of 1 mm, 2 mm, 3 mm, and 4 mm, respectively.

As stated above, a substrate on a surface on which a pattern by a conductive paste for measuring contact resistance was printed was fired using a near-infrared firing furnace with a halogen lamp as a source of heat (a high speed firing furnace for solar cells manufactured by DESPATCH) in the air under predetermined conditions. Like the test product of the single-crystalline silicon solar cells of Experiment 1, the firing conditions are as follows: fired at a peak temperature of 800° C. in the air by putting the substrate in and out of the furnace for 60 seconds. In this manner, an electrode for measuring contact resistance was produced experimentally. Three samples of the same conditions were prepared, and the measurement value was determined as a mean value of the three samples.

Measurement of contact resistance was performed as stated above using the electrode pattern as shown in FIG. 7. The contact resistance was determined by measuring the electrical resistance between the predetermined rectangle electrode patterns as shown in FIG. 7, and separating the contact resistance component and the sheet resistance component. When the contact resistance is 100 mΩ·cm² or less, the electrode can be used as an electrode for a single-crystalline silicon solar cell. When the contact resistance is 25 mΩ·cm² or less, the electrode can preferably be used as an electrode for a crystalline silicon solar cell. When the contact resistance is 10 mΩ·cm² or less, the electrode can more preferably be used as an electrode of a crystalline silicon solar cell. Furthermore, when the contact resistance is 350 mΩ·cm² or less, it might be possible to use the electrode as an electrode of a crystalline silicon solar cell. When the contact resistance exceeds 350 mΩ·cm², however, it would be difficult to use the electrode as an electrode for a crystalline silicon solar cell.

As is clear from Table 4, when a conductive paste of the present invention containing a complex oxide (a glass frit) of Samples b to f is used, a contact resistance of 20.1 mΩ·cm² or less can be achieved. FIG. 2 shows the regions including the composition ranges of the complex oxides (glass frits) of Samples b to f as Region 1 and Region 2. The composition range of Region 1 in FIG. 2 is a composition region consisting of the ranges of 35-65 mol % of molybdenum oxide, 5-45 mol % of boron oxide, and 25-35 mol % of bismuth oxide, when the total of molybdenum oxide, boron oxide and bismuth oxide is taken as 100 mol %. Furthermore, the composition range of Region 2 in FIG. 2 is a composition region consisting of the ranges of 15-40 mol % of molybdenum oxide, 25-45 mol % of boron oxide, and 25-60 mol % of bismuth oxide, when the total of molybdenum oxide, boron oxide and bismuth oxide is taken as 100 mol %.

As is clear from Table 4, when a conductive paste of the present invention containing a complex oxide (a glass frit) of Samples c, d, and e is used, a low contact resistance of 7.3 mΩ·cm² or less can be achieved. That is, of the composition range of Region 1 in FIG. 2, when a complex oxide (a glass flit) having a composition region consisting of the ranges of 35-65 mol % of molybdenum oxide, 5-35 mol % of boron oxide and 25-35 mol % of bismuth oxide, when the total of molybdenum oxide, boron oxide and bismuth oxide is taken as 100 mol %, is used, lower contact resistance can be said to be achieved.

### Experiment 3

### Structure of Crystalline Silicon Solar Cell

A single-crystalline silicon solar cell was produced experimentally using a conductive paste containing a complex oxide (a glass flit) of Sample d in Table 4 in the same manner as that of Example 1 except for the composition of the complex oxide, and a cross-sectional shape of the single-crystalline silicon solar cell was observed using a scanning electron microscope (SEM) and a transmission electron microscope (TEM) to reveal the structure of the crystalline silicon solar cell of the present invention.

FIG. 4 shows a scanning electron microscope (SEM) micrograph of a cross-sectional surface of a crystalline silicon solar cell of the present invention, more specifically, an SEM micrograph around the interface between a single-crystalline silicon substrate and a light-incident side electrode 20. For comparison, FIG. 3 shows an SEM micrograph of a cross-sectional surface of a crystalline silicon solar cell, which is produced experimentally in the same manner as Comparative Examples 5, more specifically, an SEM micrograph around the interface between a single-crystalline silicon substrate and a light-incident side electrode 20 and its surroundings. FIG. 5 shows a transmission electron microscope (TEM) micrograph of the cross-sectional view of the crystalline silicon solar cell of FIG. 4, showing an enlarged area including the interface between the single-crystalline silicon substrate and the light-incident side electrode. FIG. 6 shows a schematic view for illustrating a transmission electron microscope micrograph of FIG. 5.

As is clear from FIG. 3, in the case of the single-crystalline silicon solar cell of Comparative Example 5, a large amount of complex oxide 24 is present between silver 22 in the light-incident side electrode 20 and a p-type crystalline silicon substrate 1. The portion where silver 22 and the p-type crystalline silicon substrate 1 are in contact with each other is very little, and is evidently at the maximum of less than 5% of the area between the light-incident side electrode 20 and the single-crystalline silicon substrate and directly below the light-incident side electrode 20. In contrast, in the case of the single-crystalline silicon solar cell as shown in FIG. 4, which is an Example of the present invention, the portion where silver 22 and the p-type crystalline silicon substrate 1 are in contact with each other is clearly much larger compared to the case of the single-crystalline silicon solar cell of the comparative example in FIG. 3. In comparison to FIG. 3, in the case of the single-crystalline silicon solar cell of FIG. 4, which is an example of the present invention, the area of the portion where silver 22 and the p-type crystalline silicon substrate 1 are in contact with each other is evidently at a minimum of no less than 5%, roughly around 10% of the area between the light-incident side electrode 20 and the single-crystalline silicon substrate and directly below the light-incident side electrode 20.

Furthermore, to further observe the detailed structure between the light-incident side electrode 20 and the single-crystalline silicon substrate, a transmission electron microscope (TEM) micrograph was taken of the cross-sectional surface of the crystalline silicon solar cell of FIG. 4. FIG. 5 shows the TEM micrograph. Furthermore, FIG. 6 shows a schematic view for illustrating the structure of the TEM micrograph of FIG. 5. As is clear from FIGS. 5 and 6, a buffer layer 30 including a silicon oxynitride film 32 and a silicon oxide film 34 is evidently present between the single-crystalline silicon substrate 1 and the light-incident side electrode 20. That is, the portion where silver 22 in the light incident side electrode 20 and the p-type crystalline silicon substrate 1 are apparently in contact with each other under the SEM shown in FIG. 4 is observed in more detail under a TEM, a buffer layer 30 is revealed to be clearly present. Furthermore, in the silicon oxide film 34, a large number of silver particulates 36 (conductive particulates) of 20 nm or less are evidently present. It should be noted that the composition analysis under TEM observation was performed by the Electron Energy-Loss Spectroscopy (EELS).

According to an inference, which is not limitative, although the silicon oxynitride film 32 and the silicon oxide film 34 are insulating films, they contribute in some way or other to the electrical contact between the single-crystalline silicon substrate 1 and the light-incident side electrode 20. Furthermore, the buffer layer 30 is believed to play the role of preventing, when the conductive paste is fired, the components or impurities in the conductive paste from diffusing to the p-type or n-type impurity diffusion layer 4 and adversely affecting the solar cell characteristics. Thus, it may be inferred that by having the structure where a buffer layer 30 including a silicon oxynitride film 32 and a silicon oxide film 34 in this order is present at at least a portion directly below the light-incident side electrode 20 of the crystalline silicon solar cell, a high performance crystalline silicon solar cell can be achieved. It may also be inferred that the silver particulates 36 contained in the buffer layer 30 further contribute to the electrical contact between the single-crystalline silicon substrate 1 and the light-incident side electrode 20.

TABLE 1

| Type of glass frit | Composition of glass frit |
|---|---|
| A1 | MoO₃—B₂O₃—Bi₂O₃—TiO₂—ZnO—SnO₂ system |
| A2 | MoO₃—B₂O₃—Bi₂O₃—TiO₂—ZnO system |
| B1 | PbO—TeO₂—Ag₂O system |
| B2 | PbO—TeO₂—Ag₂O system |
| C1 | PbO—TeO₂—Bi₂O₃—ZnO—WO₃ system |
| C2 | PbO—TeO₂—Bi₂O₃—ZnO—WO₃ system |
| D1 | PbO—SiO₂—Al₂O₃—P₂O₅—TiO₂—ZnO system |
| D2 | PbO—SiO₂—Al₂O₃—P₂O₅—TiO₂—ZnO system |

TABLE 2

| | Type of glass frit | | | |
|---|---|---|---|---|
| Components of glass frit | A1 | A2 | D1 | D2 |
| MoO₃ (mol %) | 49.0 | 49.0 | | |
| B₂O₃ (mol %) | 19.6 | 19.6 | | |
| Bi₂O₃ (mol %) | 29.4 | 29.4 | | |
| TiO₂ (mol %) | 0.7 | 0.6 | 2.0 | 1.9 |
| ZnO (mol %) | 1.3 | 1.3 | 1.8 | 1.3 |
| WO₃ (mol %) | | | | |
| SnO₂ (mol %) | | 0.1 | | |
| PbO (mol %) | | | 59.2 | 54.8 |
| SiO₂ (mol %) | | | 27.9 | 33.3 |
| Al₂O₃ (mol %) | | | 6.3 | 5.9 |
| TeO₂ (mol %) | | | | |
| P₂O₅ (mol %) | | | 2.8 | 2.8 |
| Ag₂O (mol %) | | | | |
| Total of glass frit components (mol %) | 100 | 100 | 100 | 100 |

TABLE 3

| | | | Comparative | Comparative | Comparative | Comparative | Comparative | Comparative |
|---|---|---|---|---|---|---|---|---|
| | Example 1 | Example 2 | Example 1 | Example 2 | Example 3 | Example 4 | Example 5 | Example 6 |
| Glass frit in | A1 | A2 | B1 | B2 | C1 | C2 | D1 | D2 |
| conductive | | | | | | | | |
| paste | | | | | | | | |
| Fill factor FF | 0.761 | 0.758 | 0.670 | 0.628 | 0.641 | 0.651 | 0.562 | 0.548 |
| Open circuit | 618.8 | 617.3 | 586.2 | 562.5 | 579.2 | 587.5 | 538.3 | 521.1 |
| voltage Voc | | | | | | | | |
| (V) | | | | | | | | |
| Short circuit | 35.14 | 35.12 | 35.41 | 36.51 | 35.76 | 36.22 | 36.44 | 36.56 |
| current density | | | | | | | | |
| Jsc (mA/cm²) | | | | | | | | |
| Conversion | 16.55 | 16.43 | 13.92 | 12.90 | 13.27 | 13.85 | 11.03 | 10.45 |
| efficiency η | | | | | | | | |
| (%) | | | | | | | | |
| Recombination | 2.99 × 10⁻⁴ | 3.78 × 10⁻⁸ | 4.25 × 10⁻⁷ | 9.57 × 10⁻⁷ | 4.99 × 10⁻⁷ | 1.99 × 10⁻⁶ | 3.05 × 10⁻⁶ | 9.97 × 10⁻⁶ |
| current J₀₂ | | | | | | | | |
| (A/cm²) | | | | | | | | |

TABLE 4

| Components of | | | | | | | |
|---|---|---|---|---|---|---|---|
| glass frit | Sample a | Sample b | Sample c | Sample d | Sample e | Sample f | Sample g |
| MoO₃ (mol %) | 20 | 30 | 40 | 50 | 60 | 30 | 10 |
| B₂O₃ (mol %) | 50 | 40 | 30 | 20 | 10 | 30 | 30 |
| Bi₂O₃ (mol %) | 30 | 30 | 30 | 30 | 30 | 40 | 60 |
| Total of three | 100 | 100 | 100 | 100 | 100 | 100 | 100 |
| components | | | | | | | |
| (mol %) | | | | | | | |
| Contact | 68.5 | 20.1 | 7.3 | 4.4 | 6.7 | 13.6 | 344 |
| resistance | | | | | | | |
| (mΩ · cm²) | | | | | | | |

### Experiment 4

### Experimental Production of Single-Crystalline Silicon Solar Cell Incorporating an n-Type Impurity Diffusion Layer 4 of Low Impurity Density

As an Example of Experiment 4, a single-crystalline silicon solar cell of Example 3 was produced experimentally in the same manner as Example 1 except that in forming an n-type impurity diffusion layer 4 (emitter layer), the n-type impurity density was set to 8×10¹⁹ cm⁻³ (junction depth: 250-300 nm, sheet resistance: 130 Ω/square), and the temperature (peak temperature) for firing a conductive paste to form an electrode was set at 750° C. That is, the complex oxide (glass flit) in the conductive paste of Example 3 was A1 in Table 2. Furthermore, the single-crystalline silicon solar cell of Example 4 was produced experimentally in the same manner as Example 3 except that the temperature (peak temperature) for firing a conductive paste was set at 775° C. Three solar cells of the same conditions were prepared, and the measurement value was determined as a mean value of the three.

As a comparative example of Experiment 4, a single-crystalline silicon solar cell of Comparative Example 7 was produced experimentally in the same manner as Example 3 except that D1 in Table 2 was used as the complex oxide (glass frit) in the conductive paste. Furthermore, a single-crystalline silicon solar cell of Comparative Example 8 was produced experimentally in the same manner as Comparative Example 7 except that the temperature (peak temperature) for firing a conductive paste was set at 775° C. Three solar cells of the same conditions were prepared, and the measurement value was determined as a mean value of the three.

It should be noted that, the impurity density of the emitter layer in the single-crystalline silicon solar cell is typically 2-3×10²⁰ cm⁻³ (sheet resistance: 90 Ω/square). Thus, the impurity density of the emitter layer of the respective single-crystalline silicon solar cells of Examples 3 and 4 and Comparative Examples 7 and 8 is as low as around ⅓ to ¼ of the impurity density of the emitter layer of a common solar cell. In general, when the impurity density of an emitter layer is low, the contact resistance between the electrode and the crystalline silicon substrate 1 is high, so that it is difficult to provide a crystalline silicon solar cell of good performance.

Table 5 shows solar cell characteristics of the single-crystalline silicon solar cells of Examples 3 and 4 and Comparative Examples 7 and 8. As shown in Table 5, the fill factors of Comparative Examples 7 and 8 were as low as 0.534 and 0.717, respectively. In contrast, the fill factors of Examples 3 and 4 were above 0.76. Furthermore, the conversion efficiencies of the single-crystalline silicon solar cells of Examples 3 and 4 were as high as not less than 18.9%. Hence, according to the present invention, it can be said that a high performance crystalline silicon solar cell can be produced even when the impurity density of the emitter layer is low.

TABLE 5

| | | Firing peak | Fill | Short circuit | | Conversion |
|---|---|---|---|---|---|---|
| | Glass frit | temperature | factor | current density | Voc | efficiency |
| Experiment 4 | composition | (° C.) | F.F. | Jsc (mA/cm²) | (V) | (%) |
| Example 3 | A1 | 750 | 0.764 | 38.30 | 0.65 | 18.93 |
| Example 4 | A1 | 775 | 0.785 | 33.08 | 0.65 | 19.38 |
| Comparative | D1 | 750 | 0.534 | 18.13 | 0.64 | 13.04 |
| Example 7 | | | | | | |
| Comparative | D1 | 775 | 0.717 | 37.89 | 0.64 | 17.43 |
| Example 8 | | | | | | |

### Experiment 5

### Impurity Density of n-Type Impurity Diffusion Layer 4 and Saturation Current Density of Emitter Directly Below Electrode

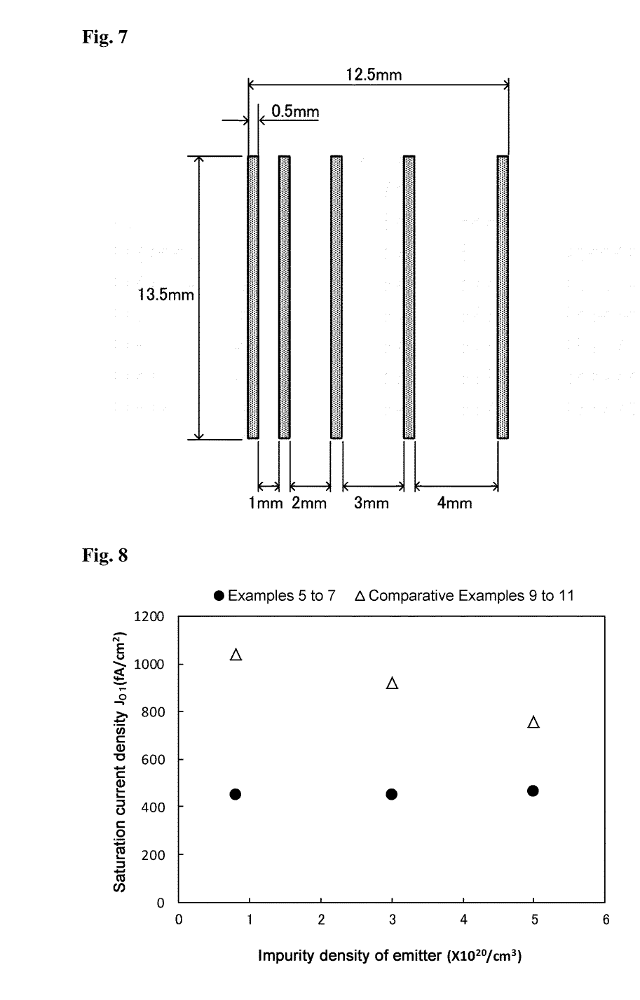

As Experiment 5, single-crystalline silicon solar cells of Examples 5-7 were produced experimentally in the same manner as Example 1 except that the impurity density of the respective emitter layers was changed. That is, A1 in Table 2 was used as the complex oxide (glass flit) in the conductive paste for Examples 5-7. Furthermore, single-crystalline silicon solar cells of Comparative Examples 9-11 were produced experimentally in the same manner as Example 5-7 except that D1 in Table 2 was used as the complex oxide (glass frit) in the conductive paste. The saturation current density (J₀₁) of the emitter layer directly below the light-incident side electrode in the respective solar cells obtained as Experiment 5 was measured. Three solar cells of the same conditions were prepared, and the measurement value was determined as a mean value of the three. The results of measurements are shown in FIG. 8. The fact that the saturation current density (J₀₁) of an emitter layer directly below the light-incident side electrode 20 is low indicates that the surface recombination rate of the carriers directly below the light-incident side electrode 20 is small. When the surface recombination rate is small, less recombination of carriers generated by the incidence of light occurs, so that a high performance solar cell can be produced.

As shown in FIG. 8, in each case of the single-crystalline silicon solar cells of Example 5-7 of Experiment 5, the saturation current density (J₀₁) of the emitter layer directly below the light-incident side electrode 20 is low compared to Comparative Examples 9-11. This can be said to indicate that in the case of the crystalline silicon solar cell of the present invention, the surface recombination rate of carriers directly below the light-incident side electrode 20 is small. Thus, in the case of the crystalline silicon solar cells of the present invention, less recombination of carriers that are generated by the incidence of light occurs, so that high performance solar cells can be produced.

TABLE 6

| | Glass | Impurity | | Error in |
|---|---|---|---|---|
| | frit | density | Saturated current | current |
| | compo- | of Emitter | density of Emitter | density |
| Experiment 5 | sition | (/cm³) | (J₀₁: fA/cm²) | (J₀₁: fA/cm²) |
| Example 5 | A1 | 5 × 10²⁰ | 464 | ±24.1 |
| Example 6 | A1 | 3 × 10²⁰ | 448 | ±36.0 |
| Example 7 | A1 | 0.8 × 10²⁰ | 449 | ±266.2 |
| Comparative | D1 | 5 × 10²⁰ | 758 | ±91.7 |
| Example 9 | | | | |
| Comparative | D1 | 3 × 10²⁰ | 922 | ±44.4 |
| Example 10 | | | | |
| Comparative | D1 | 0.8 × 10²⁰ | 1039 | ±163.6 |
| Example 11 | | | | |

### Experiment 6

### Relationship Among Area of Dummy Electrode Section, Open Circuit Voltage, and Saturation Current Density of Emitter

As Experiment 6, single-crystalline silicon solar cells having different areas of the dummy electrode sections on the emitter layers were produced experimentally. Then, the open circuit voltage, which is one of solar cell characteristics, and the saturation current density of the respective emitters were measured. A dummy electrode section refers to an electrode which is not electrically connected to a bus bar electrode section (unconnected to a bus bar electrode section). In proportion to the area of the dummy electrode section, the surface recombination of carriers at the dummy electrode section increases. Thus, finding the relationship between an increase in the area of the dummy electrode section, and open circuit voltage and the saturation current density of the emitter enables clarification of the state of decrease in solar cell performance attributable to surface recombination of carriers on the surface of the emitter layer directly below the light-incident side electrode 20.

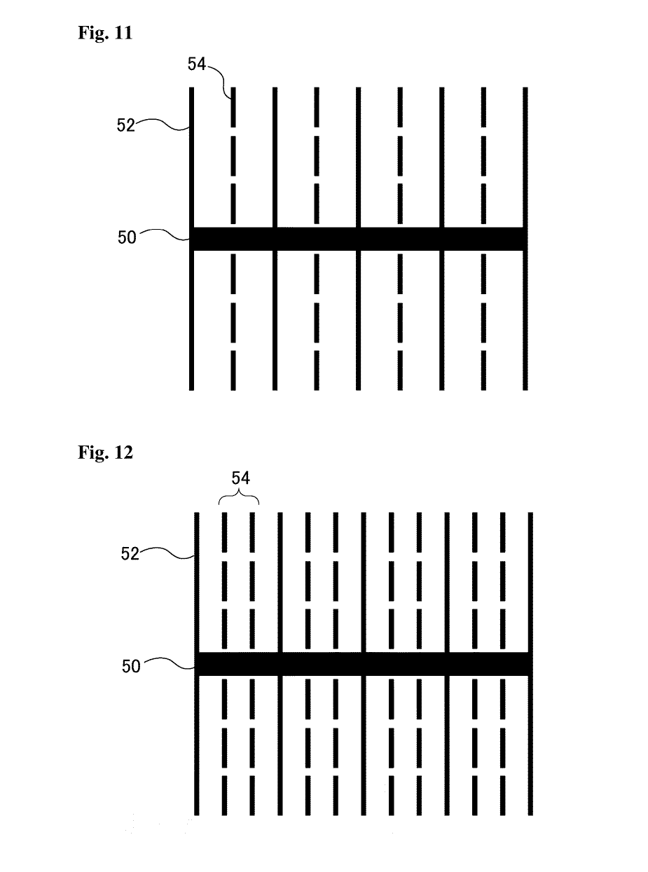

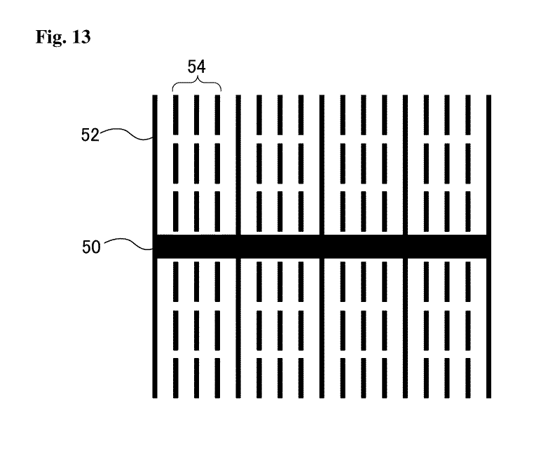

To change the area of the dummy electrode section, predetermined solar cells each including a light-incident side electrode 20, which includes a bus bar electrode section 50, a finger electrode section (connecting finger electrode section 52) connected to the bus bar electrode section 50, and a dummy finger electrode section 54 of different numbers (0 to 3) arranged between the connecting finger electrode sections 52, were prepared. For reference, FIGS. 11, 12 and 13 show schematic views of electrodes having one, two, and three dummy finger-electrode sections 54 between the connecting finger electrode sections 52. In the form of the actually used electrodes, the bus bar electrode section 50 and the connecting finger electrode sections 52 were disposed such that sixty four connecting finger electrode sections 52 (100 μm wide, 140 mm long) were orthogonal at their center to a single bus bar electrode section 50 (2 mm wide, 140 mm long). The connecting finger electrode sections 52 were spaced apart from one another at an interval of 2.443 mm at their center. The dummy finger electrode section 54 was in the form of a dashed line, and the dash-like portions, each having a length of 5 mm and a width of 100 μm, are arranged in series with an interval of 1 mm. A predetermined number of the dashed line-like dummy finger electrode sections 54 were arranged with equal intervals between connecting finger electrode sections 52. The bus bar electrode section 50 and connecting finger electrode sections 52 are connected such that taking out of current to the outside is possible, so that the properties of the solar cell can be measured. The dummy finger electrode sections 54 are not connected to the bus bar electrode section 50, and are isolated.

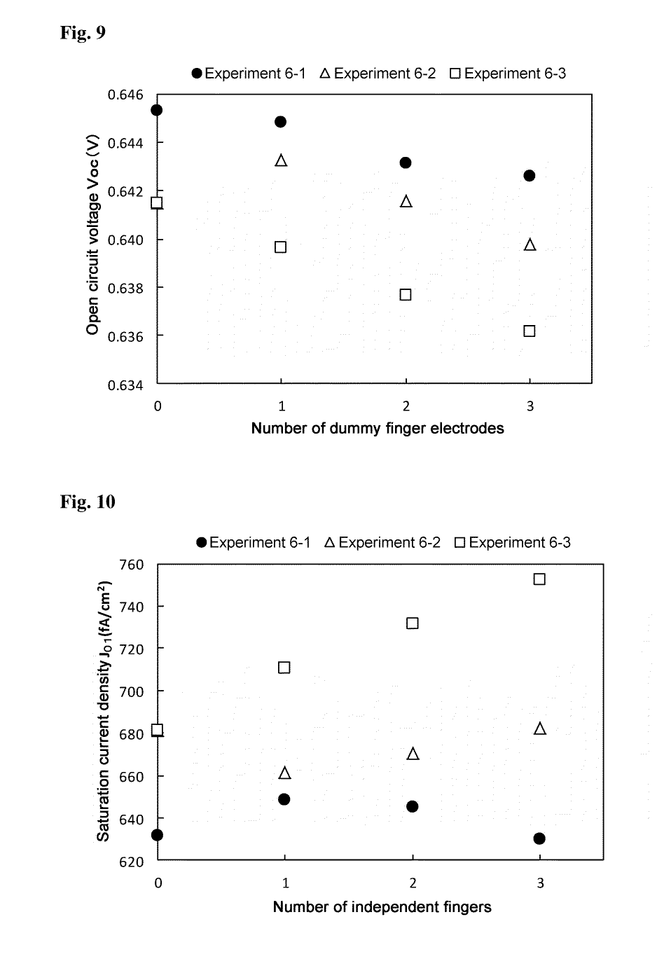

As shown in Table 7, in Experiments 6-1, 6-2, and 6-3, single-crystalline silicon solar cells were produced experimentally using the predetermined conductive paste to form a bus bar electrode section 50 and a connecting finger electrode section 52, and a dummy finger electrode section 54. The production conditions of the solar cells were the same as those of Example 1 except that those in Table 7 were used as a glass frit in the respective conductive pastes. Three solar cells were prepared under the respective conditions, and the mean value of the three was taken as the value of the respective data. The results are shown in Table 7. Furthermore, the results of measurements of the open circuit voltages (Voc) in Experiment 6 are depicted in FIG. 9. The results of measurements of saturation current densities (J₀₁) in Experiment 6 are shown in FIG. 10.

As is clear from Table 7, in the case of the solar cell of Experiment 6-1, a dummy finger electrode section 54 was prepared using a conductive paste containing the complex oxide (glass fit) of A1, which is an example of the present invention. Compared to Experiment 6-2 and Experiment 6-3, where a conventional conductive paste containing the complex oxide (glass frit) of D1 is used, high open circuit voltage (Voc) and low saturation current density (J₀₁) can clearly be achieved in the case of the solar cell of Experiment 6-1. It is inferred that forming an electrode of a solar cell using a conductive paste of the present invention made it possible to reduce the surface recombination rate of carriers directly below the electrode.

TABLE 7

| | Exper- | Exper- | Exper- |
|---|---|---|---|
| | iment | iment | iment |
| | 6-1 | 6-2 | 6-3 |
| Glass frit in the conductive paste | A1 | D1 | D1 |
| for bus bar electrode section and | | | |
| connecting finger electrode section | | | |
| Glass frit in the conductive paste | A1 | A1 | D1 |
| for dummy finger electrode section | | | |
| Open circuit voltage Voc (V) | | | |
| Number of dummy finger electrode | 0.6453 | 0.6415 | 0.6415 |
| sections = 0 | | | |
| Number of dummy finger electrode | 0.6448 | 0.6433 | 0.6396 |
| sections = 1 | | | |
| Number of dummy finger electrode | 0.6431 | 0.6416 | 0.6376 |
| sections = 2 | | | |
| Number of dummy finger electrode | 0.6426 | 0.6398 | 0.6361 |
| sections = 3 | | | |
| Saturation current density J₀₁ | | | |
| (fA/cm²) | | | |
| Number of dummy finger electrode | 631.42 | 681.44 | 681.44 |
| sections = 0 | | | |
| Number of dummy finger electrode | 648.73 | 661.62 | 710.86 |
| sections = 1 | | | |
| Number of dummy finger electrode | 644.86 | 670.75 | 731.41 |
| sections = 2 | | | |
| Number of dummy finger electrode | 629.90 | 682.36 | 752.68 |
| sections = 3 | | | |

### EXPLANATION OF LETTERS AND NUMERALS

1. Crystalline silicon substrate (p-type crystalline silicon substrate)
2. Anti-reflection film
4 Impurity diffusion layer (n-type impurity diffusion layer)
15 Back surface electrode
20 Light-incident side electrode (surface electrode)
22 Silver
24 Complex oxide
30 Buffer layer
32 Silicon oxynitride film
34 Silicon oxide film
36 Silver particulate
50 Bus bar electrode section
52 Connecting finger electrode section
54 Dummy finger electrode section

1. A crystalline silicon solar cell comprising:
a first conductivity-type crystalline silicon substrate;
an impurity diffusion layer formed on at least a portion of at least one surface of the crystalline silicon substrate;
a buffer layer formed on at least a portion of a surface of the impurity diffusion layer; and
an electrode formed on a surface of the buffer layer,
wherein
the electrode comprises a conductive metal and a complex oxide, and
the buffer layer is a layer comprising silicon, oxygen, and nitrogen.

2. The crystalline silicon solar cell according to claim 1, wherein the buffer layer comprises a conductive metallic element, silicon, oxygen, and nitrogen.

3. The crystalline silicon solar cell according to claim 2, wherein the conductive metallic element contained in the buffer layer is silver.

4. The crystalline silicon solar cell according to claim 1, comprising an anti-reflection film made of silicon nitride on at least a portion of the surface of the impurity diffusion layer corresponding to a portion where the electrode is not formed,
wherein the impurity diffusion layer is a second conductivity-type impurity diffusion layer formed on a surface on a light incident side of the first conductivity-type crystalline silicon substrate, and
the electrode is an electrode formed on the surface of the light incident side of the crystalline silicon substrate.

5. The crystalline silicon solar cell according to claim 4, wherein the electrode on the light incident side comprises a finger electrode section for electrically contacting the impurity diffusion layer, and a bus bar electrode section for electrically contacting the finger electrode section and a conductive ribbon for taking out current to the outside, wherein the buffer layer is formed between the finger electrode section and the crystalline silicon substrate, and at at least a portion directly below the finger electrode section.

6. The crystalline silicon solar cell according to claim 4, comprising a back surface electrode formed on a back surface of the crystalline silicon substrate, opposite from the surface on the light incident side.

7. The crystalline silicon solar cell according to claim 1, wherein the impurity diffusion layer consists of a first conductivity-type impurity diffusion layer and a second conductivity-type impurity diffusion layer both formed on a back surface of the first conductivity-type crystalline silicon substrate, opposite from the surface on the light incident side;
the first conductivity-type impurity diffusion layer and the second conductivity-type impurity diffusion layer, each formed in a shape of a comb and disposed to interdigitate with each other;
the buffer layer includes a buffer layer formed on at least a portion of a surface of the first conductivity-type impurity diffusion layer and a buffer layer formed on at least a portion of a surface of the second conductivity-type impurity diffusion layer; and
the electrode includes a first electrode, which is formed on a surface of the buffer layer formed on the at least a portion of the surface of the first conductivity-type impurity diffusion layer, and a second electrode, which is formed on a surface of the buffer layer formed on the at least a portion of the surface of the second conductivity-type impurity diffusion layer.

8. The crystalline silicon solar cell according to claim 7, comprising a silicon nitride film made of silicon nitride formed on at least a portion of the back surface of the first conductivity-type crystalline silicon substrate and the impurity diffusion layer corresponding to a portion where the electrodes are not formed.

9. The crystalline silicon solar cell according to claim 1, wherein at least a portion of the buffer layer includes a silicon oxynitride film and a silicon oxide film, in the recited order, from the crystalline silicon substrate toward the electrodes.

10. The crystalline silicon solar cell according to claim 9, wherein the buffer layer comprises conductive particulates.

11. The crystalline silicon solar cell according to claim 10, wherein the conductive particulates have a particle size of 20 nm or less.

12. The crystalline silicon solar cell according to claim 10, wherein the conductive particulates are present only within the silicon oxide film of the buffer layer.

13. The crystalline silicon solar cell according to claim 10, wherein the conductive particulates are silver particulates.

14. The crystalline silicon solar cell according to claim 1, wherein the buffer layer disposed between the electrode and the impurity diffusion layer has an area not less than 5% of an area directly below the electrode.

15. The crystalline silicon solar cell according to claim 1, wherein the complex oxide contained in the electrode comprises molybdenum oxide, boron oxide, and bismuth oxide.

16. The crystalline silicon solar cell according to claim 15, wherein, when the total of molybdenum oxide, boron oxide, and bismuth oxide is taken as 100 mol %, the complex oxide contains 25-65 mol % of molybdenum oxide, 5-45 mol % of boron oxide, and 25-35 mol % of bismuth oxide.

17. A method for producing a crystalline silicon solar cell, the method comprising:
preparing a first conductivity-type crystalline silicon substrate;
forming an impurity diffusion layer on at least a portion of at least one surface of the crystalline silicon substrate;
forming a silicon nitride film on a surface of the impurity diffusion layer; and
printing and firing a conductive paste on a surface of the silicon nitride film, which is formed on the surface of the impurity diffusion layer, to form an electrode and a buffer layer between the electrode and the impurity diffusion layer,
wherein the buffer layer is a layer comprising silicon, oxygen, and nitrogen.

18. The method for producing a crystalline silicon solar cell according to claim 17, wherein the buffer layer is a layer comprising a conductive metallic element, silicon, oxygen, and nitrogen.

19. The method for producing a crystalline silicon solar cell according to claim 18, wherein the conductive metallic element contained in the buffer layer is silver.

20. The method for producing a crystalline silicon solar cell according to claim 17,
wherein the impurity diffusion layer is a second conductivity-type impurity diffusion layer formed on a surface on the light incident side of the first conductivity-type crystalline silicon substrate, and
the electrode is an electrode formed on the surface on the light incident side of the crystalline silicon substrate.

21-34. (canceled)
